(19) United States
(12) Patent Application Publication
(10) Pub. No.: US 2012/0104380 A1
(43) Pub. Date: May 3, 2012

(54) CONDUCTING FORMULATION

(75) Inventors: Mark James, Romsey (GB); Magda Goncalves-Miskiewicz, Southamton (GB); Ruth Effenberger, Undenheim (DE); Klaus Bonrad, Alsbach-Haehnlein (DE)

(73) Assignee: Merck Patent GmbH, Darmstadt (DE)

(21) Appl. No.: 13/379,927

(22) PCT Filed: May 31, 2010
(86) PCT No.: PCT/EP10/03294

§ 371 Date: Dec. 21, 2011

(30) Foreign Application Priority Data
Jun. 22, 2009 (EP) 09008131.6

(51) Int. Cl. H01L 51/54; H01B 1/12; H01L 51/56

(52) U.S. Cl. 257/40; 438/46; 252/500; 252/519.21; 257/E51.026

(57) ABSTRACT

The present invention relates to novel formulations comprising light emitting materials and/or charge transporting materials and a conductive additive, to their use as conducting inks for the preparation of organic light emitting diode (OLED) devices, to methods for preparing OLED devices using the novel formulations, and to OLED devices prepared from such methods and formulations.

### FIELD OF THE INVENTION

The present invention relates to novel formulations comprising light emitting materials and/or charge transporting materials and a conductive additive, to their use as conducting inks for the preparation of organic light emitting diode (OLED) devices, to methods for preparing OLED devices using the novel formulations, and to OLED devices prepared from such methods and formulations.

### BACKGROUND AND PRIOR ART

When preparing OLED devices, usually printing techniques like inkjet printing, roll to roll printing, slot dye coating, flexographic or gravure printing are used to apply the active layer. Contact printing techniques like gravure printing operate at high speed. However, high speed coating of a substrate with an ink or fluid, containing light emitting materials and/or charge transporting materials, can lead to a build up of static charge if the fluid is not conducting. This can lead to an electrostatic discharge by arcing, and, if the solvent is flammable, result in a fire or explosion. This hazard can be reduced by engineering solutions such as the use of tinsel and electrostatic neutralization bars. However, the rapid pumping of a non-conductive flammable fluid to a coating or printing head can also lead to electrostatic discharge.

Another possibility to reduce or avoid the building of static charge is to use conducting solvents. The static charge is then harmlessly dissipated to earth via contact with conductive surfaces on the printer. As a result, no static charge accumulates and arcing does not occur. However, this can put serious restraints on the possible choice of solvents for the fluid, containing light emitting materials and/or charge transporting materials. For example, the limited solubility of conjugated polymers for the fluid, containing light emitting materials and/or charge transporting materials, for printed OLEDs requires the use of organic solvents and especially aromatic or heteroaromatic solvents, such as o-xylene. However, these solvents are virtually non-conductive and will therefore imply the above-mentioned problems due to static charge.

Surprisingly it has been found that it is possible to include a conductivity enhancing additive to the semiconductor fluid which avoids building of static charges. The conductivity of the resultant fluid should be on the order from 10⁻⁵ to 10⁻⁹ Siemens/meter (S/m). The concentration of the additive should be as low as possible. The additive should not adversely affect the performance and lifetime of the devices.

Adding a conductive additive to a light emitting material and/or charge transporting material is described in prior art as a measure to increase conductivity of the semiconductor. However, when using a fluid comprising standard light emitting materials and/or charge transporting materials, like conjugated polymers in an aromatic hydrocarbon solvent, it was so far not possible to achieve the required conductivity without permanently doping the polymer (for example with iodine or other oxidants). For the uses of the present invention, however, permanent doping is undesired as it would lead to a deterioration of the OLED device performance.

For example, US 2006/0175582 discloses a composition for preparing hole injection layers (HIL) or hole transport layers (HTL) for electroluminescent devices. The composition comprises for example a conjugated polymer, like e.g. poly(3-substituted thiophene), a solvent and an oxidant. The oxidant is used to permanently dope the polymer in order to increase its conductivity. Accordingly, US 2006/0175582 suggests to use oxidants preferably in high concentrations and selected from highly oxidising additives and/or additives that will remain in the polymer after processing. However, this is exactly the effect that should be avoided by the materials and methods used in the present invention.

EP 0 822 236 A1 discloses a composition comprising a film-forming polymer matrix, an intrinsically conductive polymer dispersed in said matrix, and a material that controls the conductivity in said composition, which is selected from the group consisting of amines, ammonia, organic hydroxyl compounds, epoxides, ethoxylated and propoxylated compounds, acrylates, methacrylates, surfactants with a pH greater than about 7 and mixtures thereof. These materials are used to increase the conductivity of the deposited film or coating of the conductive polymer, and can also be added to the polymer blend after film formation. Again, this is what should be avoided by the materials and methods used in the present invention.

It is therefore desirable to have fluids comprising light emitting materials and/or charge transporting materials that are suitable for the preparation of OLED devices, which allow a broader selection of possible solvents, do not lead to problems of static charge as mentioned above, and will not lead to permanent doping of the light emitting materials and/or charge transporting materials or otherwise adversely affect the performance and lifetime of the device. One aim of the present invention is to provide such improved fluids. Another aim is to provide improved methods of preparing an OLED device from such fluids. Another aim is to provide improved OLED devices obtained from such fluids and methods. Further aims are immediately evident to the person skilled in the art from the following description.

Surprisingly it has been found that these aims can be achieved, and the above-mentioned problems can be solved, by providing methods, materials and devices as claimed in the present invention, especially by providing a process for preparing an OLED device using a low conducting ink based on a non-conducting solvent. In particular, it has been found that it is possible to provide an ink with a low conductivity, which is sufficiently high to avoid the building of static charge in the printing process used for depositing the light emitting materials and/or charge transporting materials onto the OLED device, but is also sufficiently low to avoid a significant negative influence on the OLED device performance. This is achieved by providing an ink comprising at least one light emitting material and/or charge transporting material and at least one non-conducting organic solvent, preferably an aromatic solvent, and further comprising a small amount of one or more conductivity enhancing agents, i.e. additives that increase the conductivity of the formulation (hereinafter also shortly referred to as “conductive additives”). The conductive additive(s) used is either volatile, so that it is evaporated together with the solvent after deposition of the layer, containing the light emitting materials and/or charge transporting materials, on the device, and is thus not remaining in the OLED device. Alternatively the conductive additive used does not have an oxidising effect on the light emitting materials and/or charge transporting materials. As a result, permanent electrical doping of the light emitting materials and/or charge transporting materials, which could render the light emitting materials and/or charge transporting materials too conductive and thereby adversely affect the desired OLED device properties, is avoided.

### SUMMARY OF THE INVENTION

The invention relates to a formulation comprising one or more organic light emitting materials and/or charge transporting materials, one or more organic solvents, and one or more additives that increase the conductivity of the formulation (conductive additives), wherein said conductive additives are volatile and/or are not capable of chemically reacting with the light emitting material and/or charge transporting material.

The invention further relates to the use of a formulation as described above and below as coating or printing ink for the preparation of OLED devices, in particular for rigid and flexible OLED devices.

The invention further relates to a process of preparing an organic light emitting diode (OLED) device, comprising the steps of
a) depositing a formulation as described above and below onto a substrate, preferably to form a film or layer,
b) removing the solvent(s) and any conductive additives that are volatile or capable of chemically reacting with the organic light emitting materials and/or charge transporting materials, for example by evaporation.

The invention further relates to an OLED device prepared from a formulation and/or by a process as described above and below.

OLED devices can for example be used for illumination, for medical illumination purposes, as signaling devices, as signage devices, and in displays. Displays can be addressed using passive matrix driving, total matrix addressing of active matrix driving. Transparent OLEDs can be manufactured by using optically transparent electrodes. Flexible OLEDs are assessable throughout the use of flexible substrates.

### DETAILED DESCRIPTION OF THE INVENTION

In order to avoid permanent doping of the organic light emitting materials and/or charge transporting materials, which consist of one or more organic light emitting material and/or charge transporting material, the conductive additives are selected from the group consisting of compounds that are volatile and/or are not capable of chemically reacting with the organic light emitting materials and/or charge transporting materials. In particular they are selected from compounds that do not have a permanent doping effect on the organic light emitting materials and/or charge transporting materials (e.g. by oxidising or otherwise chemically reacting with the organic light emitting materials and charge transporting material), or from volatile compounds, or both. Therefore, the formulation preferably should not contain additives, like e.g. oxidants or protonic or lewis acids, which react with the organic light emitting materials and charge transporting materials by forming ionic products. Also, the formulation preferably should not contain additives which are not volatile and cannot be removed from the solid organic light emitting materials and/or charge transporting materials after processing. In case additives are used which may electrically dope the organic light emitting materials and/or charge transporting materials, like carboxylic acids, they should preferably be selected from volatile compounds so that they can be removed from the organic film, containing light emitting materials and/or charge transporting materials, after its deposition.

It can also be tolerable to add conductive additives like for example oxidants, lewis acids, protic inorganic acids or non-volatile protic carboxylic acids, to the formulation. However, the total concentration of these additives in the formulation should then be less than 5%, preferably less than 2.5%, more preferably less than 0.5%, most preferably less than 0.1% by weight. Preferably, however, the formulation does not contain dopants selected from this group.

Thus, preferably the conductive additives are selected such that they do not permanently dope the organic light emitting materials and/or charge transporting materials, and/or they are removed from the organic light emitting materials and/or charge transporting materials after processing (wherein processing means for example depositing the organic light emitting materials and/or charge transporting materials on a substrate or forming a layer or film thereof), and/or they are present in a concentration low enough to avoid a significant effect on the OLED properties, caused for example by permanent doping. Furthermore, preferably the conductive additives are not chemically bound to the organic light emitting materials and/or charge transporting materials or the film or layer comprising it.

Preferred conductive additives are selected from the group consisting of compounds that do not oxidise the organic light emitting materials and/or charge transporting materials or otherwise chemically react with these materials. The terms “oxidise” and “chemically react” as used above and below refer to a possible oxidation or other chemical reaction of the conductive additive with the organic light emitting materials and/or charge transporting materials under the conditions used for manufacture, storage, transport and/or use of the formulation and the OLED device.

Further preferred conductive additives are selected from the group consisting of volatile compounds. The term “volatile” as used above and below means that the additive can be removed from the organic light emitting materials and/or charge transporting materials by evaporation, after the organic light emitting materials and/or charge transporting materials have been deposited onto a substrate of an OLED device, under conditions (like temperature and/or reduced pressure) that do not significantly damage the organic light emitting materials and/or charge transporting materials or the OLED device. Preferably this means that the additive has a boiling point or sublimation temperature of <300° C., more preferably ≦135° C., most preferably ≧120° C., at the pressure employed, very preferably at atmospheric pressure (1013 hPa). Evaporation can also be accelerated e.g. by applying heat and/or reduced pressure.

Suitable and preferred conductive additives that do not oxidise or otherwise chemically react with the organic light emitting materials and/or charge transporting materials are selected from the group consisting of soluble organic salts, i.e. “non-oxidising organic salts”, like for example permanent quaternary ammonium salts, phosphonium salts, imidazolium salts and other heterocyclic salts, wherein the anion is for example selected from the group consisting of halides, sulfates, acetate, formate, tetrafluoroborate, hexafluorophosphate, methanesulfonate, triflate (trifluoromethane-sulfonate), bis(trifluoromethyl-sulfonyl)imide or others, and the cation is for example selected from the group consisting of tetraalkyl ammonium, tetraaryl ammonium or mixed tetra alkyl-aryl ammonium ions, wherein the alkyl or aryl groups may be identical or different from each other, furthermore heterocyclic ammonium salts (e.g. ionic liquids), protonated alkyl or aryl ammonium salts or other nitrogen based salts such as dilauryl ammonium salts. Further preferred conductive additives are selected from the group consisting of alkali metal salts such as alkali metal bis(trifluoromethylsulfonyl)imide salts, or inorganic salts.

Very preferred organic salts are for example tetra-n-butyl ammonium chloride, tetraoctyl ammonium bromide, benzyl tridecylammonium benzene sulfate, diphenyl didodecyl ammonium hexafluorophosphate, N-Methyl-N-trioctyl-ammonium bis(trifluoromethylsulfonyl)imide, or mixtures thereof.

Further preferred are volatile organic salts. Suitable and preferred volatile organic salts are e.g. ammonium acetates, formiates, triflates or methanesulfonates, such as trimethylammonium acetate, triethylammonium acetate, dihexylammonium methanesulfonate, octylammonium formate, DBN (1,5-diazabicyclo[4.3.0]non-5-ene)acetate or mixtures or precursors thereof. A preferred additive of this type is e.g. a mixture of tributylamine and trifluoroacetic acid, which produces tributylammonium trifluoroacetate in the formulation, or a mixture of a tri-(C₁-C₄)-alkyl amine (preferably with a boiling point 200° C., more preferably ≦135° C.) and a volatile organic acid (preferably with a boiling point ≦200° C., more preferably ≦135° C., and a pKa value that is equal to or higher than the pKa value of acetic acid).

Further preferred conductive additives are alcohols, preferably volatile alcohols, volatile carboxylic acids, and organic amines, preferably volatile organic amines, very preferably alkyl amines.

Suitable and preferred alcohols or volatile alcohols are for example isopropyl alcohol, iso-butanol (2-butanol), hexanol, methanol or ethanol.

Suitable and preferred volatile carboxylic acids are for example those having a boiling point of ≦135° C., more preferably ≦120° C. (at atmospheric pressure), like e.g. formic acid, acetic acid, di- or trifluoroacetic acid. Other carboxylic acids, like propionic or higher acids, di- or trichloroacetic acid or methanesulfonic acid, are also tolerable and can be used if their concentration is chosen low enough to avoid significant doping of the organic light emitting materials and/or charge transporting materials, and is from more than 0 to less than 5%, preferably less than 2.5%, more preferably less than 0.5%, most preferably less than 0.1% by weight.

Suitable and preferred organic amines or volatile organic amines are alkyl amines, for example primary or secondary alkyl amines, such as n-dibutylamine, ethanolamine or octylamine.

In case of conductive additives that are not removed from the organic light emitting materials and/or charge transporting materials after deposition of the layer, like e.g. soluble organic salts or non-volatile alcohols or amines as mentioned above, some of these compounds can also have a permanent doping effect even if they do not oxidise or otherwise react with the layer, comprising the organic light emitting materials and/or charge transporting materials, e.g. by trapping charges flowing through the device. Therefore, the concentration of these additives should be kept low enough so that the device performance is not substantially negatively affected. The maximum tolerable concentration for each of these additives in the formulation can be chosen depending on its capability of permanently doping the organic light emitting materials and/or charge transporting materials.

Preferably the formulation comprises one to five conductive additives, more preferably one, two or three conductive additives, most preferably one conductive additive.

The conductivity of the formulation of the present invention is preferably from 10⁻⁵ to 10⁻⁹ S/m, more preferably from 10⁻⁶ to 10⁻⁸ S/m.

The solvents are preferably selected from the group consisting of aromatic hydrocarbons, like toluene, o-, m- or p-xylene, trimethyl benzenes (e.g. 1,2,3-, 1,2,4- and 1,3,5-trimethyl benzenes), tetralin, other mono-, di-, tri- and tetraalkylbenzenes (e.g. diethylbenzenes, methylcumene, tetramethylbenzenes etc), anisole, alkyl anisoles (e.g. 2, 3 and 4 isomers of methylanisole, 2,3-, 2,4-, 2,5-, 2,6-, 3,4- and 3,5-isomers of dimethylanisole), naphthalene derivatives, alkyl naphthalene derivatives (e.g. 1- and 2-methylnaphthalene), di- and tetrahydronaphthalene derivatives. Also preferred are aromatic esters (e.g alkyl benzoates), aromatic ketones (e.g. acetophenone, propiophenone), alkyl ketones (e.g. cyclohexanone), heteroaromatic solvents (e.g. thiophene, mono-, di- and trialkyl thiophenes, 2-alkylthiazoles, benzthiazoles etc, pyridines), halogenaryles and anilin derivatives.

Most preferred are: 3-fluoro-trifluoromethylbenzene, trifluoromethylbenzene, dioxane, trifluoromethoxybenzene, 4-fluoro-benzenetrifluoride, 3-fluoropyridine, toluene, 2-fluorotoluene, 2-fluoro-benzenetrifluoride, 3-fluorotoluene, pyridine, 4-fluorotoluene, 2,5-difluorotoluene, 1-chloro-2,4-difluorobenzene, 2-fluoropyridine, 3-chlorofluorobenzene, 1-chloro-2,5-difluoro-benzene, 4-chlorofluorobenzene, chlorobenzene, 2-chlorofluorobenzene, p-xylene, m-xylene, o-xylene, 2,6-lutidine, 2-fluoro-m-xylene, 3-fluoro-o-xylene, 2-chlorobenzenetrifluoride, dimethylformamide, 2-chloro-6-fluorotoluene, 2-fluoroanisole, anisole, 2,3-dimethylpyrazine, bromobenzene, 4-fluoroanisole, 3-fluoroanisole, 3-trifluoromethylanisole, 2-methylanisole, phenetol, benzenedioxol, 4-methylanisole, 3-methylanisole, 4-fluoro-3-methylanisole, 1,2-dichlorobenzene, 2-fluorobenzenenitril, 4-fluoroveratrol, 2,6-dimethylanisole, aniline, 3-fluorobenzenenitril, 2,5-dimethylanisole, 3,4-dimethylanisole, 2,4-dimethylanisole, benzenenitril, 3,5-dimethylanisole, N,N-dimethylaniline, 1-fluoro-3,5-dimethoxybenzene, phenylacetate, N-methylaniline, methylbenzoate, N-methylpyrrolidone, morpholine, 1,2-dihydro-naphthalene, 1,2,3,4-tetrahydronaphthalene, 3,4-dimethylanisole, o-tolunitril, veratrol, ethylbenzoate, N,N-diethylaniline, propylbenzoate, 1-methylnaphthalene, butylbenzoate, 2-methylbiphenyl, 2-phenylpyridin or 2,2′-Bitolyl.

In case a volatile additive is used, the solvent should be selected such that it can be evaporated from the coated or printed layer, comprising the organic light emitting materials and/or charge transporting materials, together with the additive, preferably in the same processing step. The processing temperature used for removing the solvent and the volatile additive should be selected such that the layer, comprising the organic light emitting materials and/or charge transporting materials, is not damaged. Preferably the deposition processing temperature is from room temperature (RT) to 135° C. and more preferably from RT to 80° C.

The organic light emitting materials and charge transporting materials can be selected from standard materials known to the skilled person and described in the literature. This includes low molecular weight materials (so called “Small Molecules”) and/or polymeric materials. Organic light emitting material according to the present application means a material which emits light having a λₘₐₓ in the range from 400 to 700 nm.

The formulation according to the present invention comprises between 0.01 and 20% by weight, preferably between 0.1 and 15% by weight, more preferably between 0.2 and 10% by weight and most preferably between 0.25 and 5% by weight, of the organic light emitting materials and/or charge transporting materials or the corresponding blend. The percent data relate to 100% of the solvent or solvent mixture.

The light emitting material or the charge transporting material (below together named as organic semiconductor) used here is either a pure component or a mixture of two or more components, at least one of which must have semiconducting properties. In the case of the use of mixtures, however, it is not necessary for each component to have semiconducting properties. Thus, for example, inert low-molecular-weight compounds can be used together with semiconducting polymers. It is likewise possible to use non-conducting polymers, which serve as inert matrix or binder, together with one or more low-molecular-weight compounds or further polymers having semiconducting properties. For the purposes of this application, the potentially admixed non-conducting component is taken to mean an electro-optically inactive, inert, passive compound.

Preference is given to solutions of polymeric organic semiconductors, which optionally comprise further admixed substances. The molecular weight M_{w} of the polymeric organic semiconductor is preferably greater than 10,000 g/mol, more preferably between 50,000 and 2,000,000 g/mol and most preferably between 100,000 and 1,000,000 g/mol.

For the purposes of the present invention, polymeric organic semiconductors are taken to mean, in particular, (i) substituted poly-p-arylenevinylenes (PAVs) as disclosed in EP 0443861, WO 94/20589, WO 98/27136, EP 1025183, WO 99/24526, DE 19953806 and EP 0964045 which are soluble in organic solvents, (ii) substituted polyfluorenes (PFs) as disclosed in EP 0842208, WO 00/22027, WO 00/22026, DE 19846767, WO 00/46321, WO 99/54385 and WO 00155927 which are soluble in organic solvents, (iii) substituted polyspirobifluorenes (PSFs) as disclosed in EP 0707020, WO 96/17036, WO 97/20877, WO 97/31048, WO 97/39045 and WO 031020790 which are soluble in organic solvents, (iv) substituted poly-para-phenylenes (PPPs) or -biphenylenes as disclosed in WO 92/18552, WO 95/07955, EP 0690086, EP 0699699 and WO 03/099901 which are soluble in organic solvents, (v) substituted polydihydrophenanthrenes (PDHPs) as disclosed in WO 05/014689 which are soluble in organic solvents, (vi) substituted poly-trans-indenofluorenes and poly-cis-indenofluorenes (PIFs) as disclosed in WO 04/041901 and WO 04/113412 which are soluble in organic solvents, (vii) substituted polyphenanthrenes as disclosed in DE 102004020298 which are soluble in organic solvents, (viii) substituted polythiophenes (PTs) as disclosed in EP 1028136 and WO 95/05937 which are soluble in organic solvents, (ix) polypyridines (PPys) as disclosed in T. Yamamoto et at., J. Am. Chem. Soc. 1994, 116, 4832 which are soluble in organic solvents, (x) polypyrroles as disclosed in V. Gelling et at., Polym. Prepr. 2000, 41, 1770 which are soluble in organic solvents, (xi) substituted, soluble copolymers having structural units from two or more of classes (i) to (x), as described, for example, in WO 02/077060, (xii) conjugated polymers as disclosed in Proc. of ICSM '98, Part I & II (in: Synth. Met 1999, 101/102) which are soluble in organic solvents, (xiii) substituted and unsubstituted polyvinylcarbazoles (PVKs), as disclosed, for example, in R. C. Penwell et al., J. Polym. Sci., Macromol Rev. 1978, 13, 63-160, (xiv) substituted and unsubstituted triarylamine polymers, as disclosed, for example, in JP 2000/072722, (xv) substituted and unsubstituted polysilylenes and polygermylenes, as disclosed, for example, in M. A. Abkowitz and M. Stolka, Synth. Met. 1996, 78, 333, and (xvi) soluble polymers containing phosphorescent units, as disclosed, for example in EP 1245659, WO 03/001616, WO 03/018653, WO 03/022908, WO 03/080687, EP 1311138, WO 031102109, WO 04/003105, WO 04/015025, DE 102004032527 and some of the specifications already cited above.

Preference is furthermore also given to solutions of non-conducting, electronically inert polymers (matrix polymers) which comprise admixed low-molecular-weight, oligomeric, dendritic, linear or branched and/or polymeric organic and/or organometallic semiconductors.

The solutions may comprise further additives which are able to change, for example, the wetting properties. Additives of this type are described, for example, in WO 03/019693.

Suitable phosphorescent compounds are, in particular, compounds which emit light, preferably in the visible region, on suitable excitation and in addition contain at least one atom having an atomic number greater than 20, preferably greater than 38 and less than 84, more preferably greater than 56 and less than 80. The phosphorescence emitters used are preferably compounds which contain copper, molybdenum, tungsten, rhenium, ruthenium, osmium, rhodium, iridium, palladium, platinum, silver, gold or europium, in particular compounds which contain iridium or platinum.

Particularly preferred organic phosphorescent compounds are compounds of formulae (1) to (4):

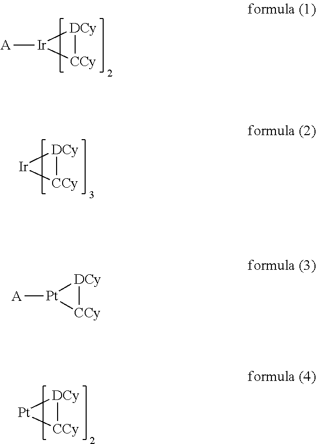

where
DCy is, identically or differently on each occurrence, a cyclic group which contains at least one donor atom, preferably nitrogen, carbon in the form of a carbene or phosphorus, via which the cyclic group is bonded to the metal, and which may in turn carry one or more substituents R¹; the groups DCy and CCy are connected to one another via a covalent bond;
CCy is, identically or differently on each occurrence, a cyclic group which contains a carbon atom via which the cyclic group is bonded to the metal and which may in turn carry one or more substituents R¹;
A is, identically or differently on each occurrence, a monoanionic, bidentate chelating ligand, preferably a diketonate ligand;
R¹ are identically or differently at each instance, and are F, Cl, Br, I, NO₂, CN, a straight-chain, branched or cyclic alkyl or alkoxy group having from 1 to 20 carbon atoms, in which one or more nonadjacent CH₂ groups may be replaced by —O—, —S—, —NR²—, —CONR²—, —CO—O—, —C═O—, —CH═CH— or —C≡C—, and in which one or more hydrogen atoms may be replaced by F, or an aryl or heteroaryl group which has from 4 to 14 carbon atoms and may be substituted by one or more nonaromatic R¹ radicals, and a plurality of substituents R¹, either on the same ring or on two different rings, may together in turn form a mono- or polycyclic, aliphatic or aromatic ring system; and
R² are identically or differently at each instance, and are a straight-chain, branched or cyclic alkyl or alkoxy group having from 1 to 20 carbon atoms, in which one or more nonadjacent CH₂ groups may be replaced by —O—, —S—, —CO—O—, —C═O—, —CH═CH— or —C≡C—, and in which one or more hydrogen atoms may be replaced by F, or an aryl or heteroaryl group which has from 4 to 14 carbon atoms and may be substituted by one or more nonaromatic R¹ radicals.

Formation of ring systems between a plurality of radicals R¹ means that a bridge may also be present between the groups DCy and CCy. Furthermore, formation of ring systems between a plurality of radicals R¹ means that a bridge may also be present between two or three ligands CCy-DCy or between one or two ligands CCy-DCy and the ligand A, giving a polydentate or polypodal ligand system.

Examples of the emitters described above are revealed by the applications WO 00/70655, WO 01/41512, WO 02/02714, WO 02/15645, EP 1191613, EP 1191612, EP 1191614, WO 04/081017, WO 05/033244, WO 05/042550, WO 05/113563, WO 06/008069, WO 06/061182, WO 06/081973 and DE 102008027005. In general, all phosphorescent complexes as are used in accordance with the prior art for phosphorescent OLEDs and as are known to the person skilled in the art in the area of organic electroluminescence are suitable, and the person skilled in the art will be able to use further phosphorescent compounds without inventive step. In particular, it is known to the person skilled in the art which phosphorescent complexes emit with which emission colour.

Examples of preferred phosphorescent compounds are shown in the following table.

| | |
|---|---|
| 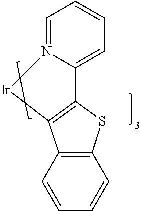 | (1) |
| 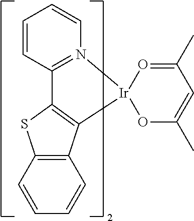 | (2) |
| 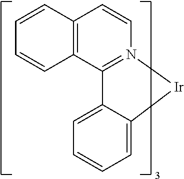 | (3) |
| 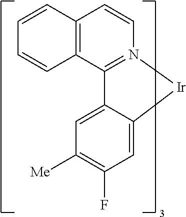 | (4) |
| 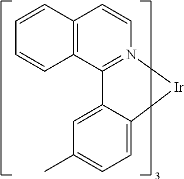 | (5) |
| 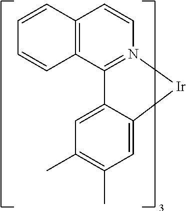 | (6) |
| 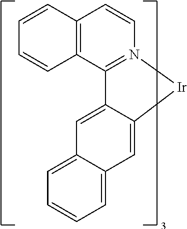 | (7) |
| 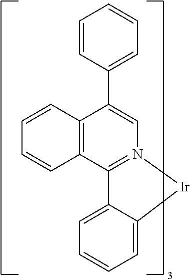 | (8) |
| 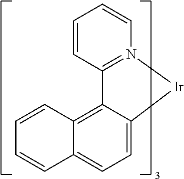 | (9) |
| 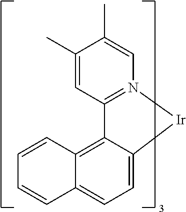 | (10) |
| 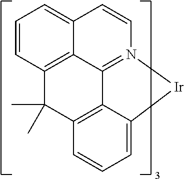 | (11) |
| 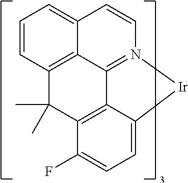 | (12) |
| 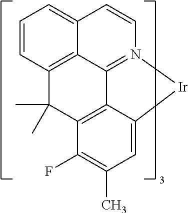 | (13) |
| 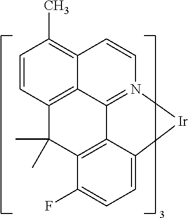 | (14) |
| 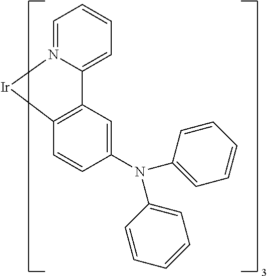 | (15) |
| 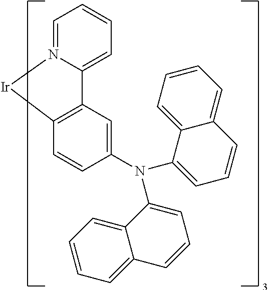 | (16) |
| 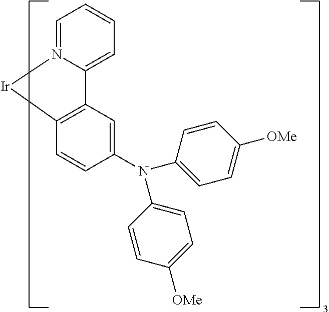 | (17) |
| 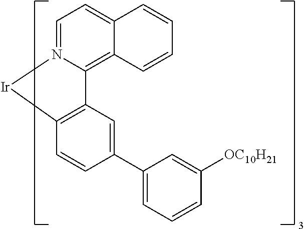 | (18) |
| 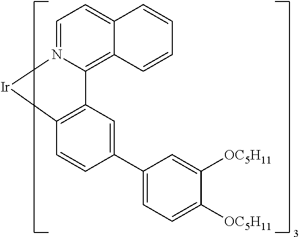 | (19) |
| 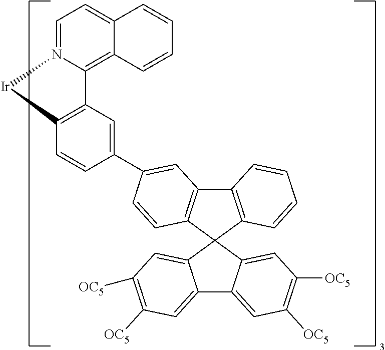 | (20) |
| 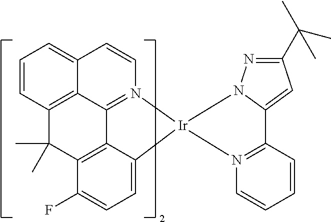 | (21) |
| 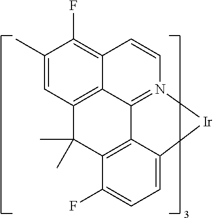 | (22) |
| 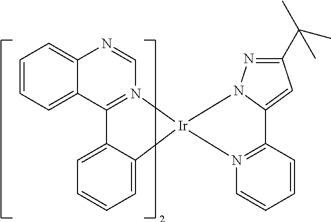 | (23) |
| 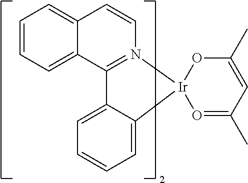 | (24) |
| 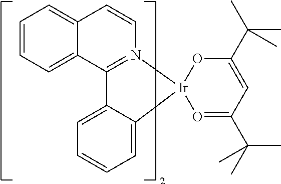 | (25) |
| 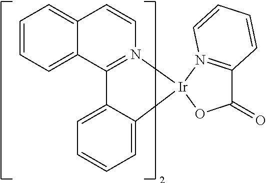 | (26) |
| 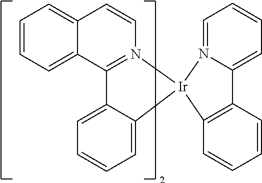 | (27) |
| 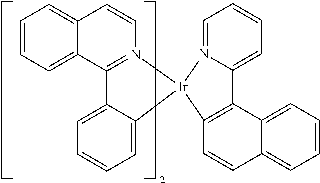 | (28) |
| 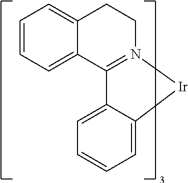 | (29) |
| 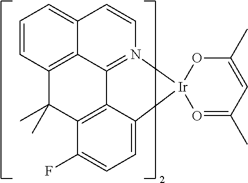 | (30) |
| 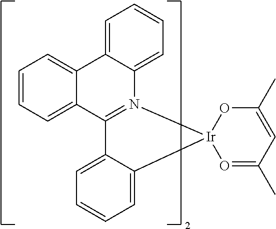 | (31) |
| 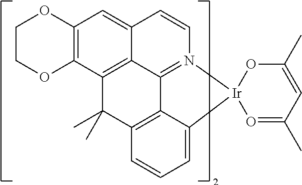 | (32) |
| 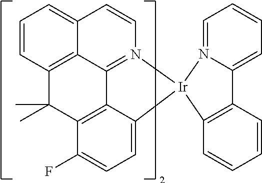 | (33) |
| 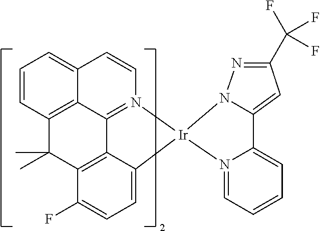 | (34) |
| 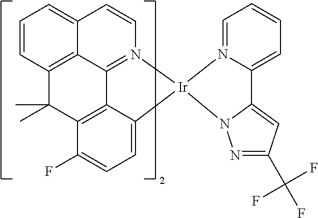 | (35) |
| 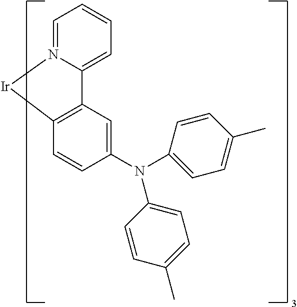 | (36) |
| 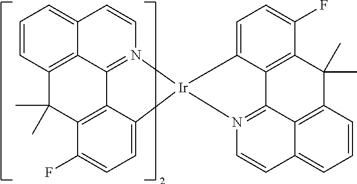 | (37) |
| 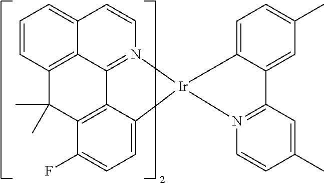 | (38) |
| 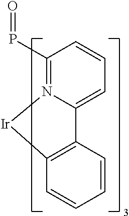 | (39) |
| 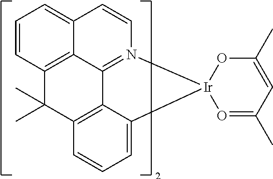 | (40) |
| 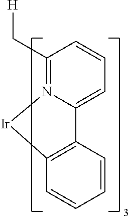 | (41) |
| 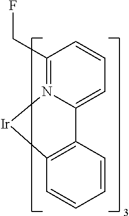 | (42) |
| 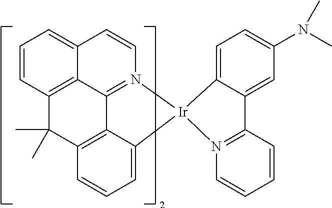 | (43) |
| 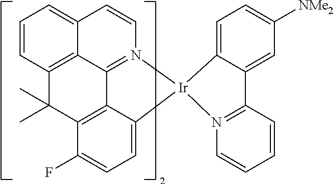 | (44) |
| 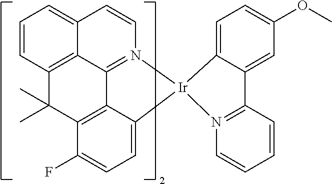 | (45) |
| 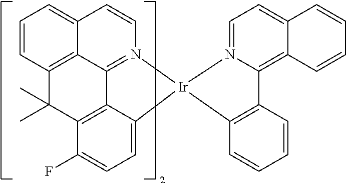 | (46) |
| 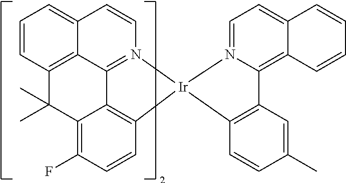 | (47) |
| 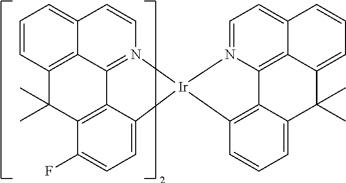 | (48) |
| 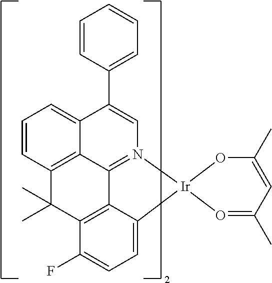 | (49) |
| 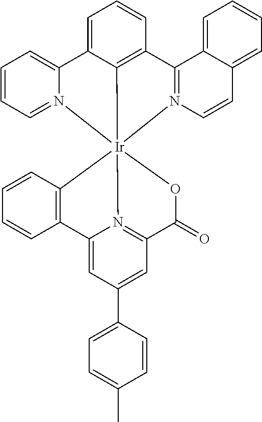 | (50) |
| 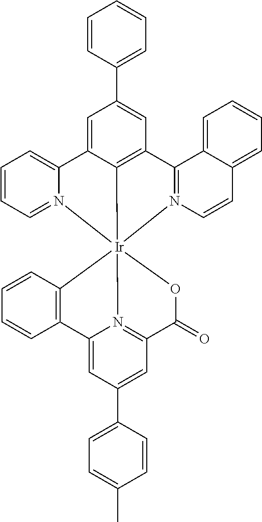 | (51) |
| 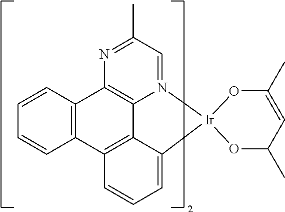 | (52) |
| 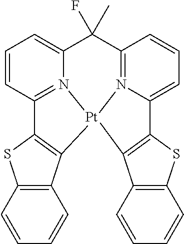 | (53) |
| 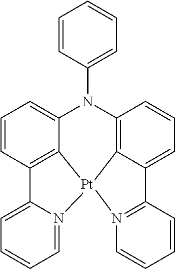 | (54) |
| 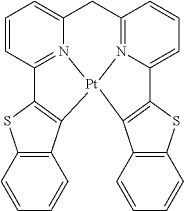 | (55) |
| 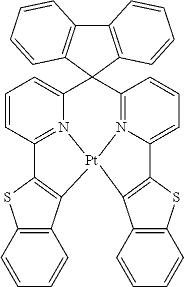 | (56) |
| 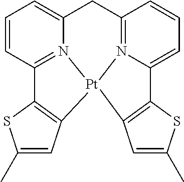 | (57) |
| 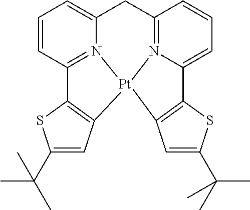 | (58) |
| 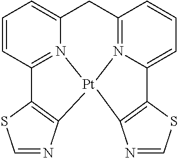 | (59) |
| 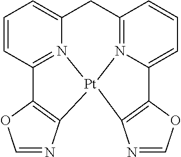 | (60) |
| 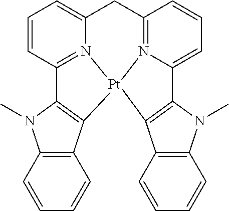 | (61) |
| 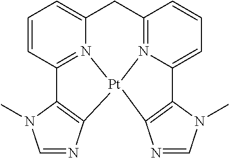 | (62) |
| 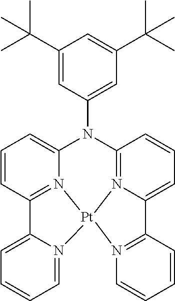 | (63) |
| 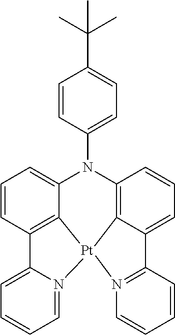 | (64) |
| 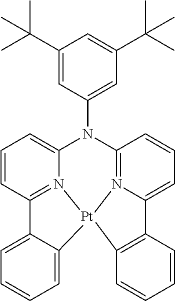 | (65) |
| 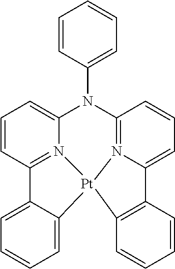 | (66) |
| 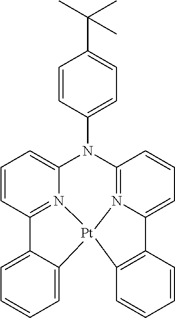 | (67) |
| 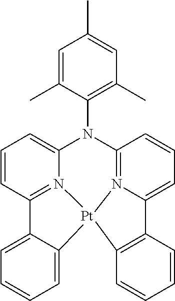 | (68) |
| 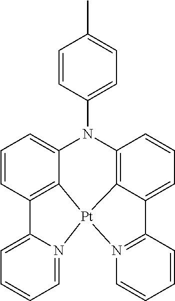 | (69) |
| 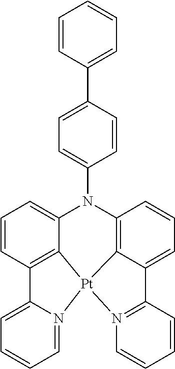 | (70) |
| 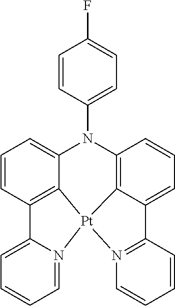 | (71) |
| 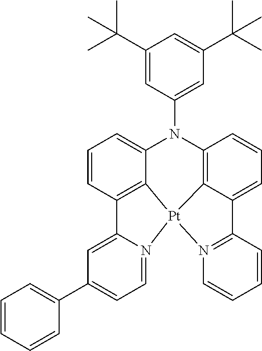 | (72) |
| 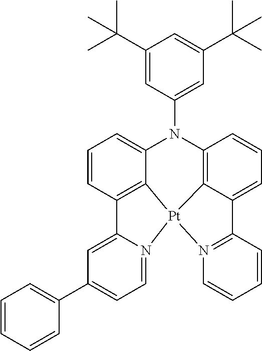 | (73) |
| 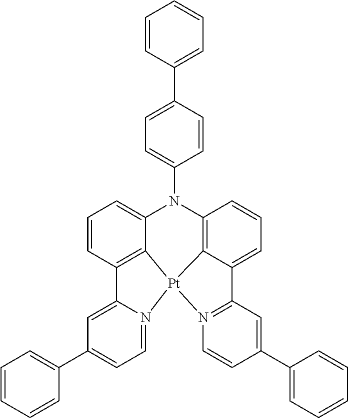 | (74) |
| 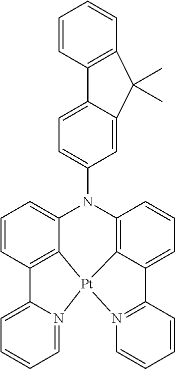 | (75) |
| 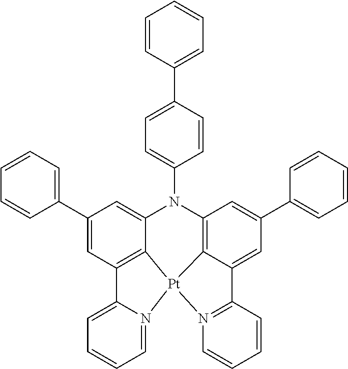 | (76) |
| 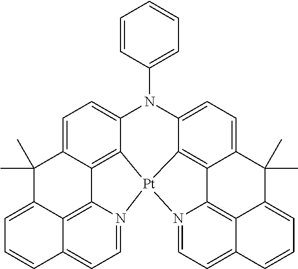 | (77) |
| 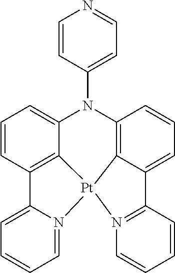 | (78) |
| 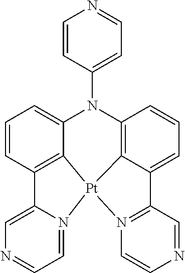 | (79) |
| 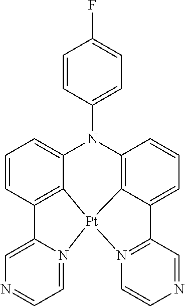 | (80) |
| 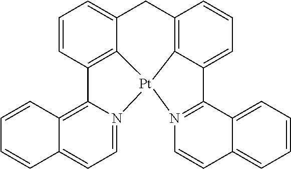 | (81) |
| 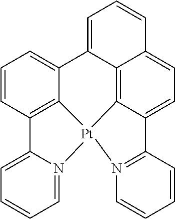 | (82) |
| 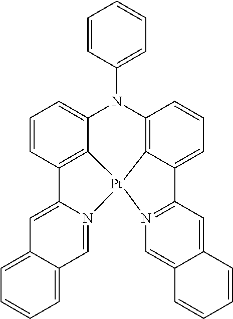 | (83) |
| 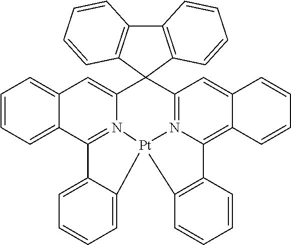 | (84) |
| 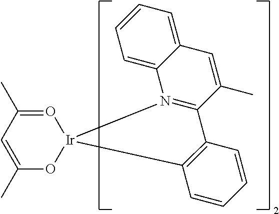 | (85) |
| 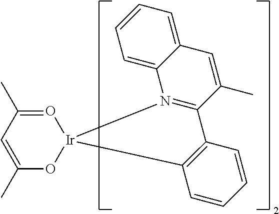 | (86) |
| 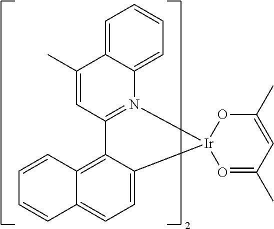 | (87) |
| 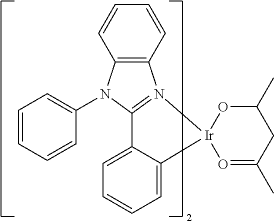 | (88) |
| 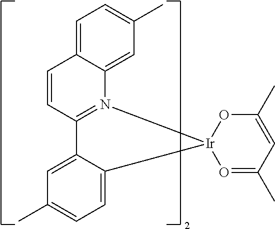 | (89) |
| 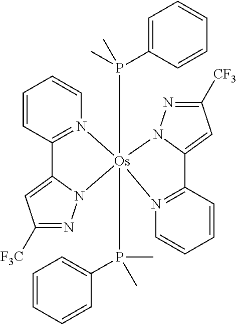 | (90) |
| 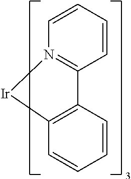 | (91) |
| 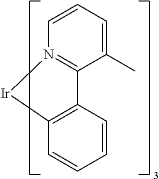 | (92) |
| 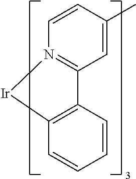 | (93) |
| 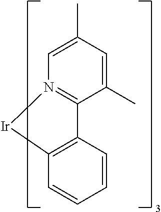 | (94) |
| 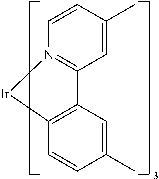 | (95) |
| 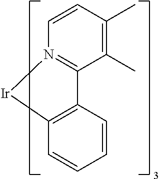 | (96) |
| 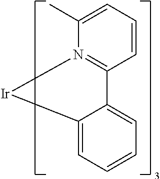 | (97) |
| 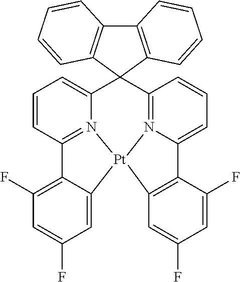 | (98) |
| 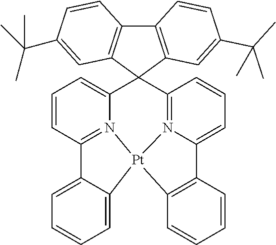 | (99) |
| 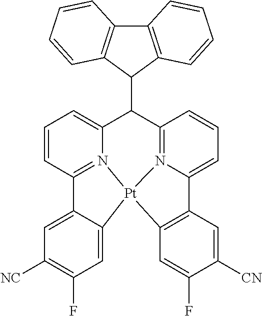 | (100) |
| 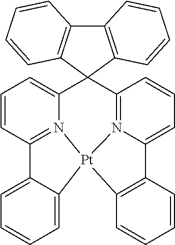 | (101) |
| 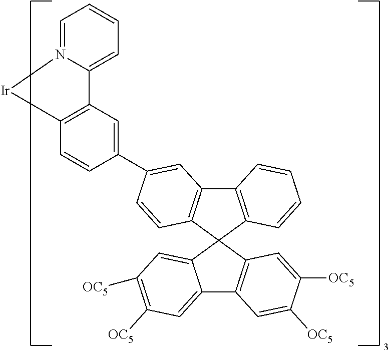 | (102) |
| 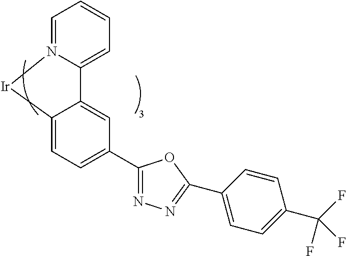 | (103) |
| 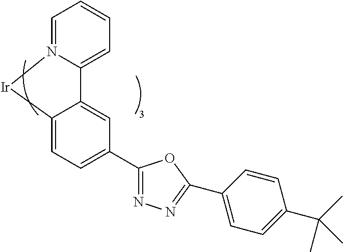 | (104) |
| 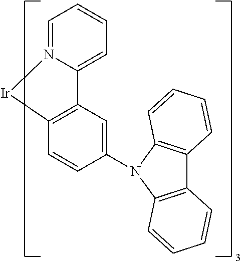 | (105) |
| 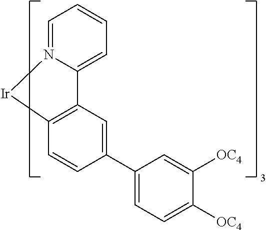 | (106) |
| 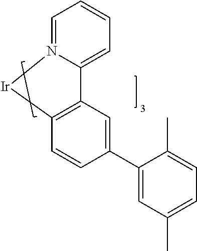 | (107) |
| 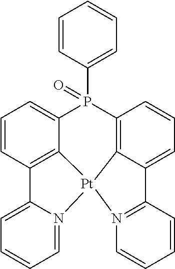 | (108) |
| 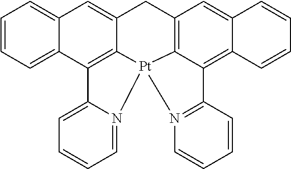 | (109) |
| 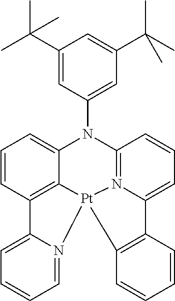 | (110) |
| 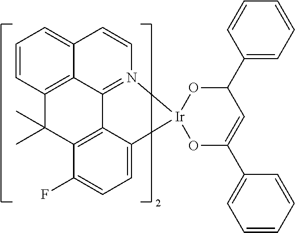 | (111) |
| 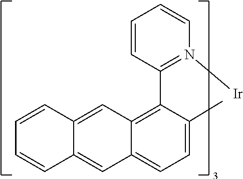 | (112) |
| 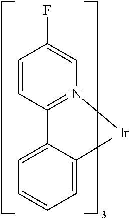 | (113) |
| 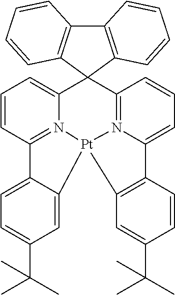 | (114) |
| 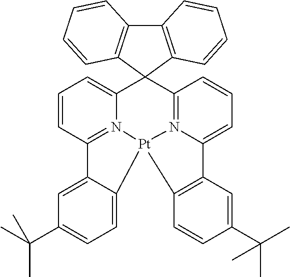 | (115) |
| 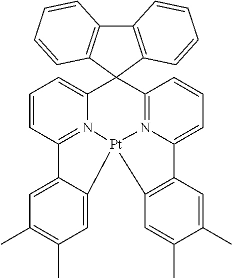 | (116) |
| 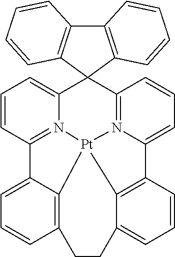 | (117) |
| 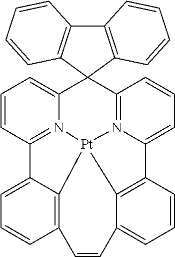 | (118) |
| 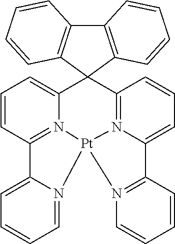 | (119) |
| 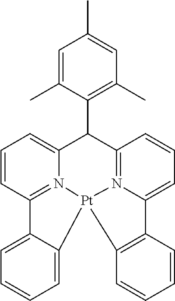 | (120) |
| 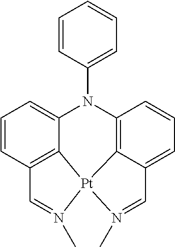 | (121) |
| 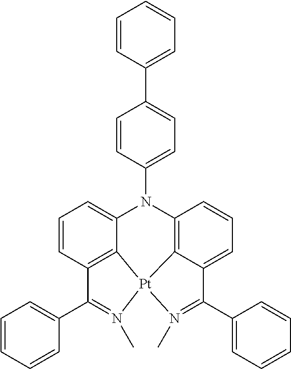 | (122) |
| 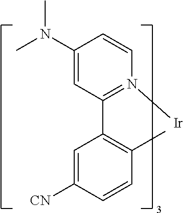 | (123) |
| 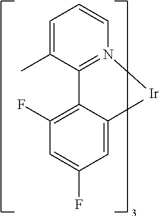 | (124) |
| 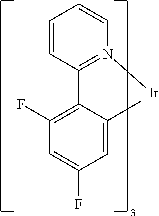 | (125) |
| 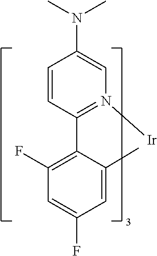 | (126) |
| 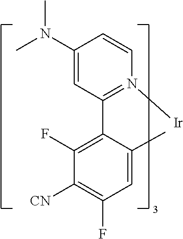 | (127) |
| 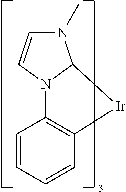 | (128) |
| 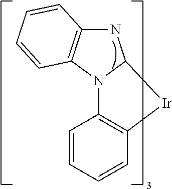 | (129) |
| 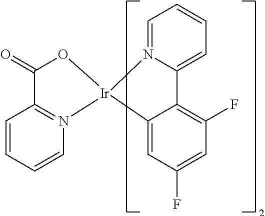 | (130) |
| 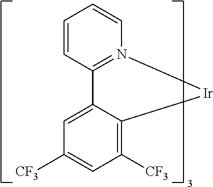 | (131) |
| 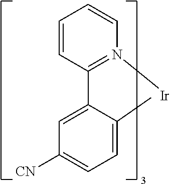 | (132) |
| 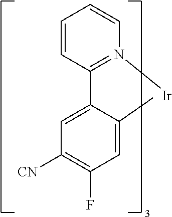 | (133) |
| 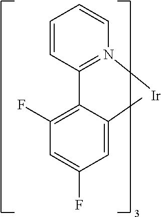 | (134) |
| 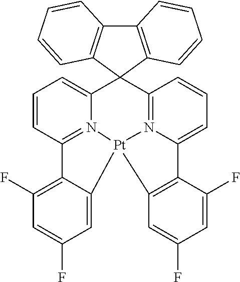 | (135) |
| 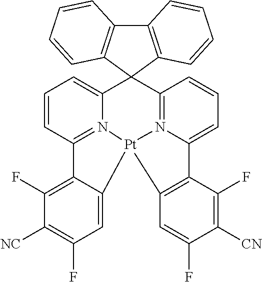 | (136) |
| 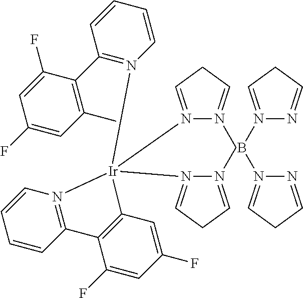 | (137) |
| 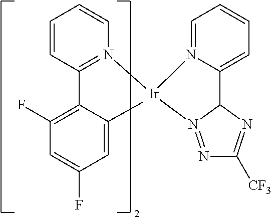 | (138) |
| 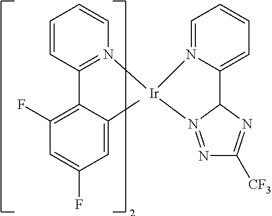 | (139) |
| 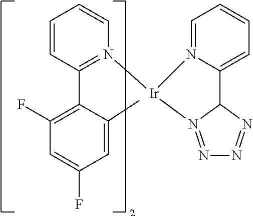 | (140) |

Preferred dopants are selected from the class of the monostyrylamines, the distyrylamines, the tristyrylamines, the tetrastyrylamines, the styrylphosphines, the styryl ethers and the arylamines. A monostyrylamine is taken to mean a compound which contains one substituted or unsubstituted styryl group and at least one, preferably aromatic, amine. A distyrylamine is taken to mean a compound which contains two substituted or unsubstituted styryl groups and at least one, preferably aromatic, amine. A tristyrylamine is taken to mean a compound which contains three substituted or unsubstituted styryl groups and at least one, preferably aromatic, amine. A tetrastyrylamine is taken to mean a compound which contains four substituted or unsubstituted styryl groups and at least one, preferably aromatic, amine. The styryl groups are particularly preferably stilbenes, which may also be further substituted. Corresponding phosphines and ethers are defined analogously to the amines. For the purposes of the present invention, an arylamine or an aromatic amine is taken to mean a compound which contains three substituted or unsubstituted aromatic or heteroaromatic ring systems bonded directly to the nitrogen. At least one of these aromatic or heteroaromatic ring systems is preferably a condensed ring system, particularly preferably having at least 14 aromatic ring atoms. Preferred examples thereof are aromatic anthraceneamines, aromatic anthracenediamines, aromatic pyreneamines, aromatic pyrenediamines, aromatic chryseneamines or aromatic chrysenediamines. An aromatic anthraceneamine is taken to mean a compound in which one diarylamino group is bonded directly to an anthracene group, preferably in the 9-position. An aromatic anthracenediamine is taken to mean a compound in which two diarylamino groups are bonded directly to an anthracene group, preferably in the 9,10-position. Aromatic pyreneamines, pyrenediamines, chryseneamines and chrysenediamines are defined analogously thereto, where the diarylamino groups are preferably bonded to the pyrene in the 1-position or in the 1,6-position. Further preferred dopants are selected from indenofluoreneamines or indenofluorenediamines, for example in accordance with WO 06/122630, benzoindenofluoreneamines or benzoindenofluorenediamines, for example in accordance with WO 08/006449, and dibenzoindenofluoreneamines or dibenzoindenofluorenediamines, for example in accordance with WO 07/140847. Examples of dopants from the class of the styrylamines are substituted or unsubstituted tristilbeneamines or the dopants described in WO 06/000388, WO 06/058737, WO 06/000389, WO 07/065549 and WO 07/115610. Preference is furthermore given to the condensed hydrocarbons disclosed in DE 102008035413.

Suitable dopants are furthermore the structures depicted in the following table, and the derivatives of these structures disclosed in JP 06/001973, WO 04/047499, WO 06/098080, WO 07/065678, US 2005/0260442 and WO 04/092111.

| | |
|---|---|
| 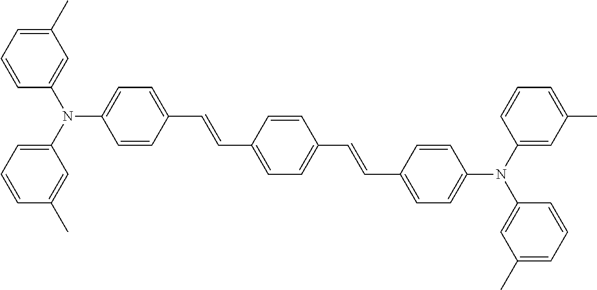 | (141) |
| 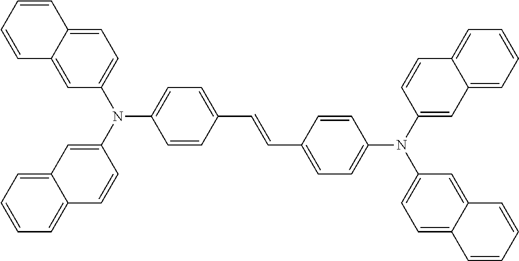 | (142) |
| 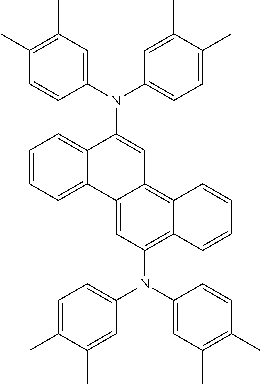 | (143) |
| 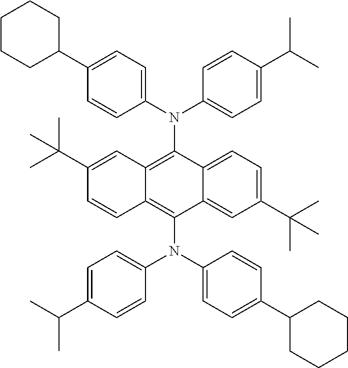 | (144) |
| 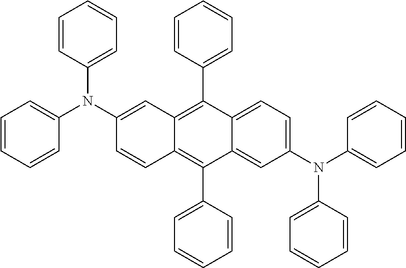 | (145) |
| 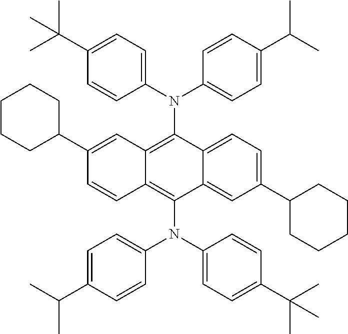 | (146) |

The proportion of the dopand in the mixture of the emitting layer is between 0.1 and 50.0% by vol., preferably between 0.5 and 20.0% by vol., particularly preferably between 1.0 and 10.0% by vol. Correspondingly, the proportion of the host material is between 50.0 and 99.9% by vol., preferably between 80.0 and 99.5% by vol., particularly preferably between 90.0 and 99.0% by vol.

Suitable host materials for this purpose are materials from various classes of substances. Preferred host materials are selected from the classes of the oligoarylenes (for example 2,2′,7,7′-tetraphenylspirobifluorene in accordance with EP 676461 or dinaphthylanthracene), in particular the oligoarylenes containing condensed aromatic groups, the oligoarylenevinylenes (for example DPVBi or spiro-DPVBi in accordance with EP 676461), the polypodal metal complexes (for example in accordance with WO 04/081017), the hole-conducting compounds (for example in accordance with WO 04/058911), the electron-conducting compounds, in particular ketones, phosphine oxides, sulfoxides, etc. (for example in accordance with WO 05/084081 and WO 05/084082), the atropisomers (for example in accordance with WO 06/048268), the boronic acid derivatives (for example in accordance with WO 06/117052) or the benzanthracenes (for example in accordance with WO 08/145239). Suitable host materials are furthermore also the benzo[c]phenanthrene compounds according to the invention which are described above. Apart from the compounds according to the invention, particularly preferred host materials are selected from the classes of the oligoarylenes containing naphthalene, anthracene, benzanthracene and/or pyrene or atropisomers of these compounds, the oligoarylenevinylenes, the ketones, the phosphine oxides and the sulfoxides. Apart from the benzo[c]phenanthrene compounds according to the invention, very particularly preferred host materials are selected from the classes of the oligoarylenes containing anthracene, benzanthracene and/or pyrene or atropisomers of these compounds. For the purposes of this invention, an oligoarylene is intended to be taken to mean a compound in which at least three aryl or arylene groups are bonded to one another.

Suitable host materials are furthermore, for example, the materials depicted in the following table, and derivatives of these materials, as disclosed in WO 04/018587, WO 08/006449, U.S. Pat. No. 5,935,721, US 2005/0181232, JP 2000/273056, EP 681019, US 2004/0247937 and US 2005/0211958.

| | |
|---|---|
| 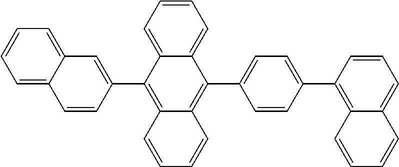 | (147) |
| 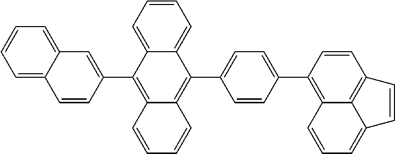 | (148) |
| 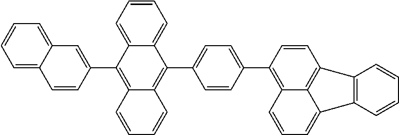 | (149) |
| 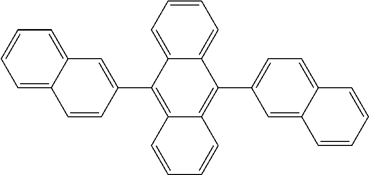 | (150) |
| 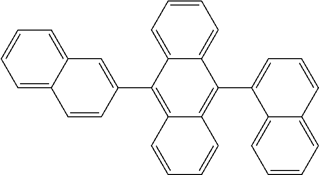 | (151) |
| 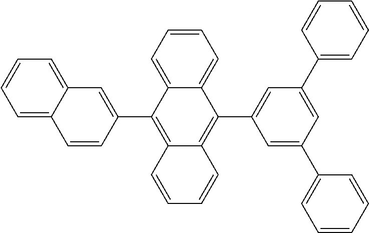 | (152) |
| 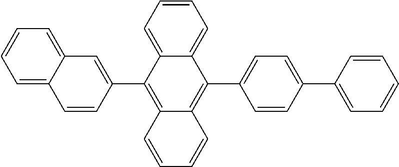 | (153) |
| 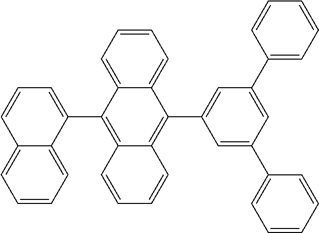 | (154) |
| 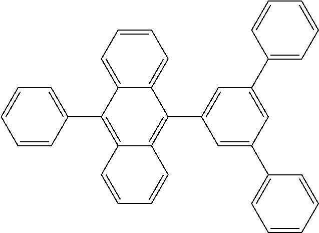 | (155) |
| 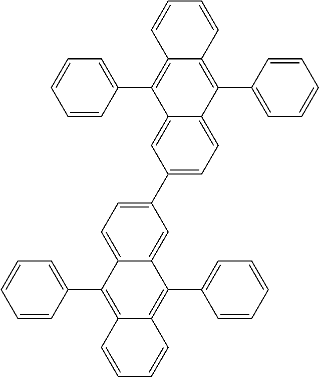 | (156) |
| 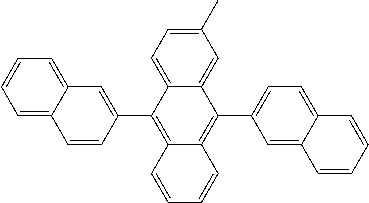 | (157) |
| 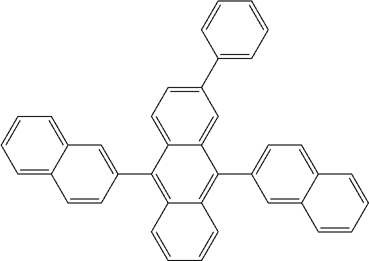 | (158) |

For the purposes of this invention, a hole-injection layer is a layer which is directly adjacent to the anode. For the purposes of this invention, a hole-transport layer is a layer which is located between a hole-injection layer and an emission layer. It may be preferred for them to be doped with electron-acceptor compounds, for example with F₄-TCNQ or with compounds as described in EP 1476881 or EP 1596445.

Apart from the materials according to the invention, suitable charge-transport materials, as can be used in the hole-injection or hole-transport layer or in the electron-injection or electron-transport layer of the organic electroluminescent device according to the invention, are, for example, the compounds disclosed in Y. Shirota et al., Chem. Rev. 2007, 107(4), 953-1010, or other materials as employed in these layers in accordance with the prior art.

Examples of preferred hole-transport materials which can be used in a hole-transport or hole-injection layer of the electroluminescent device according to the invention are indenofluoreneamines and derivatives (for example in accordance with WO 06/122630 or WO 06/100896), the amine derivatives as disclosed in EP 1661888, hexaazatriphenylene derivatives (for example in accordance with WO 01/049806), amine derivatives with condensed aromatics (for example in accordance with U.S. Pat. No. 5,061,569), the amine derivatives as disclosed in WO 95/09147, monobenzoindenofluoreneamines (for example in accordance with WO 08/006449) or dibenzoindenofluoreneamines (for example in accordance with WO 07/140847). Suitable hole-transport and hole-injection materials are furthermore derivatives of the compounds depicted above, as disclosed in JP 2001/226331, EP 676461, EP 650955, WO 01/049806, U.S. Pat. No. 4,780,536, WO 98/30071, EP 891121, EP 1661888, JP 2006/253445, EP 650955, WO 06/073054 and U.S. Pat. No. 5,061,569.

Suitable hole-transport or hole-injection materials are furthermore, for example, the materials indicated in the following table.

| | |
|---|---|
| 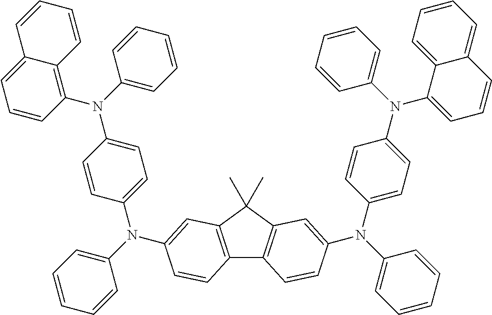 | (159) |
| 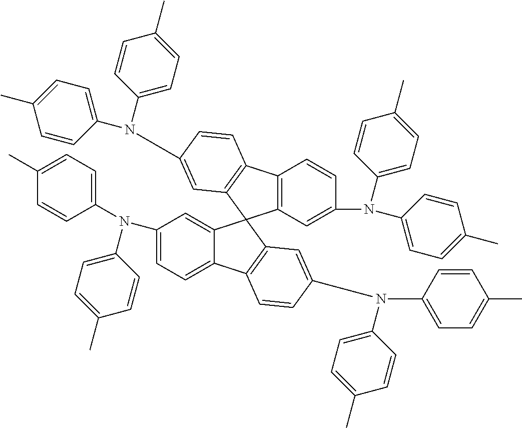 | (160) |
| 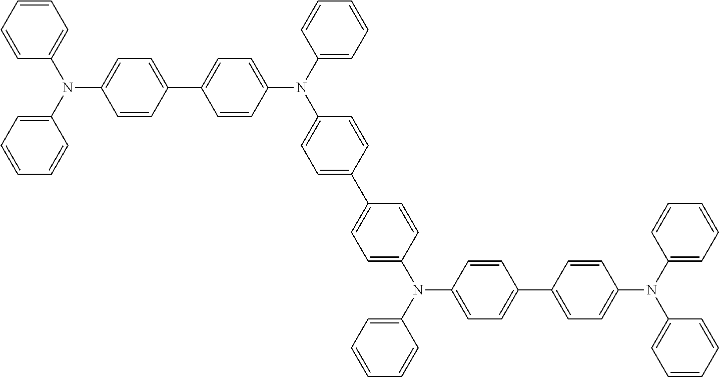 | (161) |
| 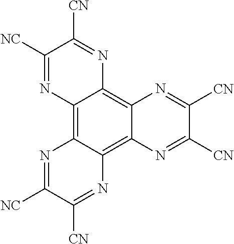 | (162) |
| 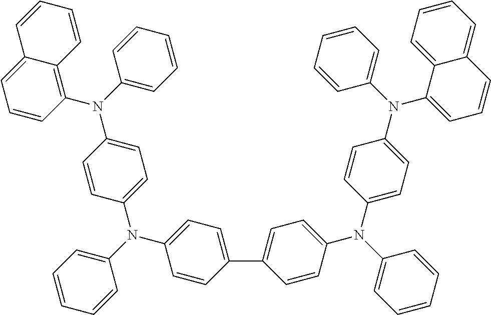 | (163) |
| 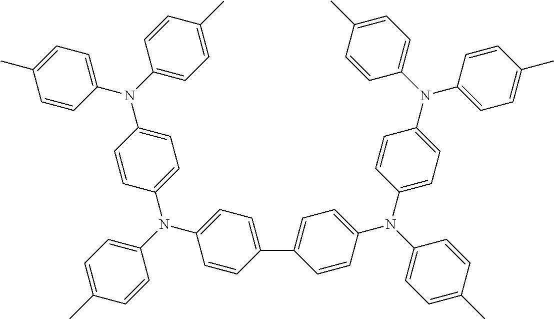 | (164) |
| 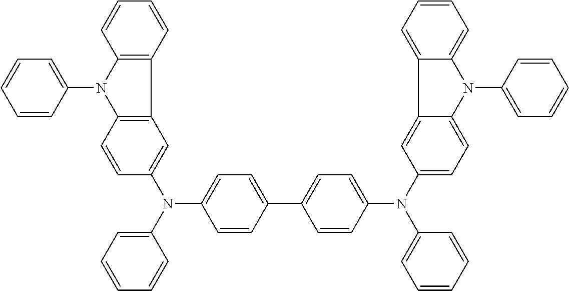 | (165) |
| 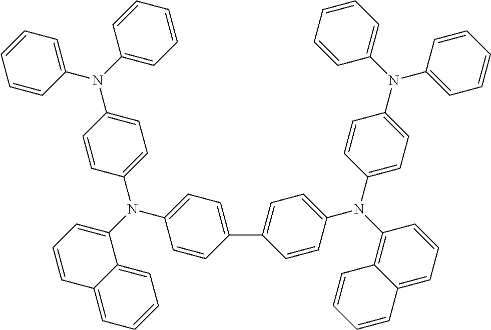 | (166) |
| 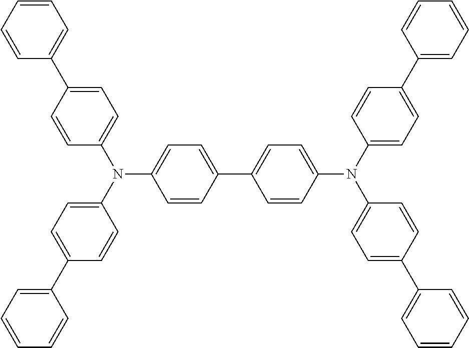 | (167) |
| 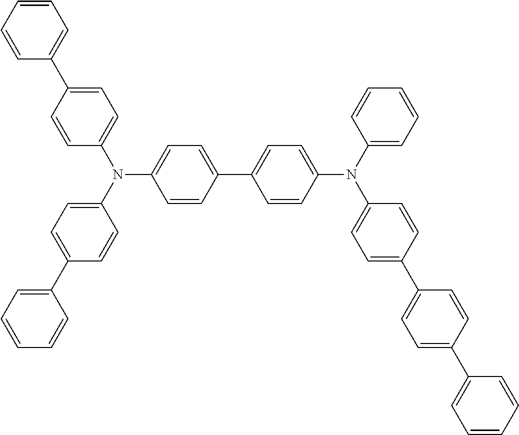 | (168) |
| 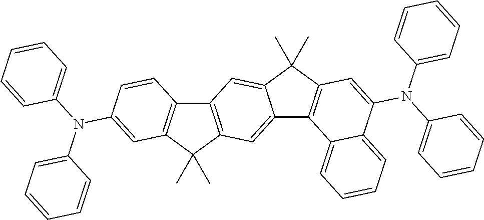 | (169) |
| 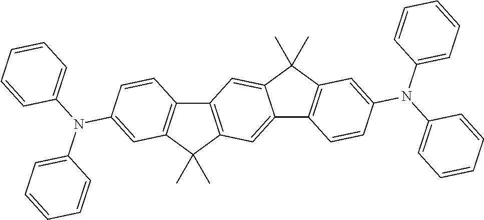 | (170) |
| 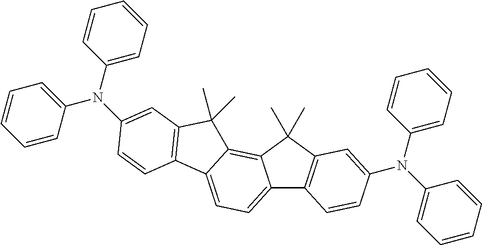 | (171) |
| 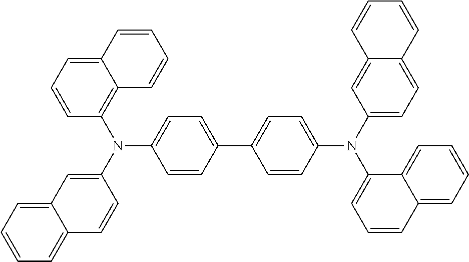 | (172) |
| 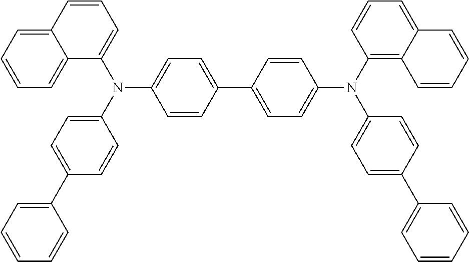 | (173) |
| 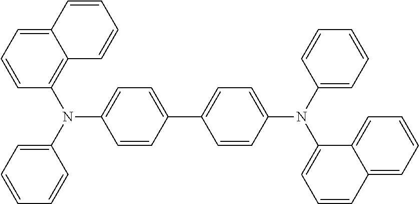 | (174) |
| 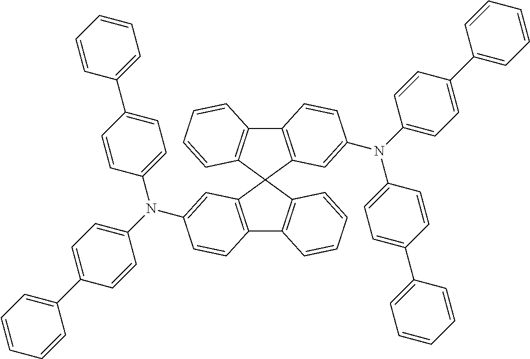 | (175) |
| 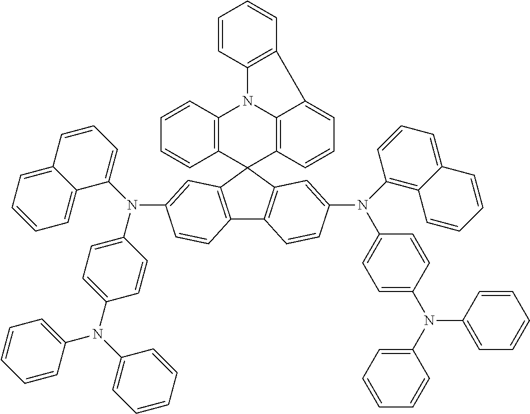 | (176) |

Suitable electron-transport or electron-injection materials which can be used in the electroluminescent device according to the invention are, for example, the materials indicated in the following table. Suitable electron-transport and electron-injection materials are furthermore derivatives of the compounds depicted above, as disclosed in JP 2000/053957, WO 03/060956, WO 04/028217 and WO 04/080975.

| | |
|---|---|
| 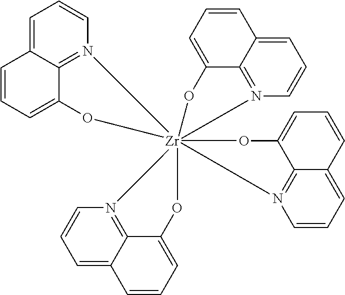 | (177) |
| 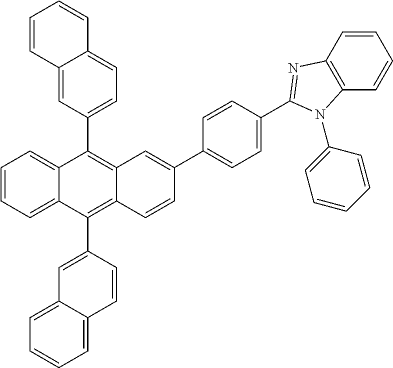 | (178) |
| 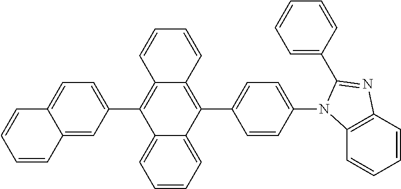 | (179) |
| 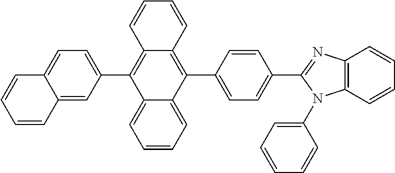 | (180) |

Suitable matrix materials for the compounds according to the invention are ketones, phosphine oxides, sulfoxides and sulfones, for example in accordance with WO 04/013080, WO 04/093207, WO 06/005627 or DE 102008033943, triarylamines, carbazole derivatives, for example CBP (N,N-biscarbazolylbiphenyl) or the carbazole derivatives disclosed in

WO 05/039246, US 2005/0069729, JP 2004/288381, EP 1205527 or WO 08/086851, indolocarbazole derivatives, for example in accordance with WO 07/063754 or WO 08/056746, azacarbazoles, for example in accordance with EP 1617710, EP 1617711, EP 1731584, JP 2005/347160, bipolar matrix materials, for example in accordance with WO 07/137725, silanes, for example in accordance with WO 05/111172, azaboroles or boronic esters, for example in accordance with WO 06/117052, triazine derivatives, for example in accordance with DE 102008036982, WO 07/063754 or WO 08/056746, or zinc complexes, for example in accordance with DE 102007053771.

Optionally, the layer, comprising the organic light emitting materials and/or charge transporting materials, comprises one or more organic binders, preferably polymeric binders, as described for example in WO 2005/055248 A1, to adjust the rheological properties, preferably in a proportion of binder to organic light emitting materials and/or charge transporting materials from 20:1 to 1:20, more preferably from 10:1 to 1:10, most preferably from 5:1 to 1:5 by weight.

The formulation according to the present invention may additionally comprise one or more further components like for example surface-active compounds, lubricating agents, wetting agents, dispersing agents, hydrophobing agents, adhesive agents, flow improvers, defoaming agents, deaerators, diluents which may be reactive or non-reactive, auxiliaries, colourants, dyes or pigments, sensitizers, stabilizers, nanoparticles or inhibitors. However, these further components should not be oxidising or otherwise capable of chemically reacting with the organic light emitting materials and/or charge transporting materials or have an electrically doping effect on the organic light emitting materials and/or charge transporting materials.

During the process of preparing an OLED device, the layer, comprising the organic light emitting materials and/or charge transporting materials, is deposited onto a substrate, followed by removal of the solvent together with any volatile conductive additive(s) present, to form a film or layer.

The substrate can be any substrate suitable for the preparation of OLED devices, or can also be the OLED device, or a part thereof. Suitable and preferred substrates are e.g. glass, ITO coated glass, ITO glass with pre coated layers including PEDOT, PANI etc, flexible films of polyethylene terephthalate (PET), polyethylene naphthalate (PEN), polyimide, and flexible films with ITO, or other conducting layers and barrier layers e.g. Vitex film.

Deposition of the layer, comprising the organic light emitting materials and/or charge transporting materials, can be achieved by standard methods that are known to the skilled person and are described in the literature. Suitable and preferred deposition methods include liquid coating and printing techniques. Very preferred deposition methods include, without limitation, dip coating, spin coating, ink jet printing, nozzle printing, letter-press printing, screen printing, gravure printing, doctor blade coating, roller printing, reverse-roller printing, offset lithography printing, flexographic printing, web printing, spray coating, dip coating, curtain coating, brush coating, slot dye coating or pad printing. Gravure, flexographic and inkjet printing are especially preferred.

Removal of the solvent and any volatile conductive additive(s) is preferably achieved by evaporation, for example by exposing the deposited layer to high temperature and/or reduced pressure, preferably at 50 to 135° C.

The thickness of the layer, comprising the organic light emitting materials and/or charge transporting materials, is preferably from 1 nm to 500 nm, more preferably from 2 to 150 nm.

Further to the materials and methods as described above and below, the OLED device and its components can be prepared from standard materials and standard methods, which are known to the person skilled in the art and described in the literature.

It will be appreciated that variations to the foregoing embodiments of the invention can be made while still falling within the scope of the invention.

Each feature disclosed in this specification, unless stated otherwise, may be replaced by alternative features serving the same, equivalent or similar purpose. Thus, unless stated otherwise, each feature disclosed is one example only of a generic series of equivalent or similar features.

All of the features disclosed in this specification may be combined in any combination, except combinations where at least some of such features and/or steps are mutually exclusive. In particular, the preferred features of the invention are applicable to all aspects of the invention and may be used in any combination. Likewise, features described in non-essential combinations may be used separately (not in combination).

It will be appreciated that many of the features described above, particularly of the preferred embodiments, are inventive in their own right and not just as part of an embodiment of the present invention. Independent protection may be sought for these features in addition to or alternative to any invention presently claimed.

Unless the context clearly indicates otherwise, as used herein plural forms of the terms herein are to be construed as including the singular form and vice versa.

Throughout the description and claims of this specification, the words “comprise” and “contain” and variations of the words, for example “comprising” and “comprises”, mean “including but not limited to”, and are not intended to (and do not) exclude other components.

The term “polymer” includes homopolymers and copolymers, e.g. statistical, alternating or block copolymers. In addition, the term “polymer” as used hereinafter does also include oligomers and dendrimers. Dendrimers are typically branched macromolecular compounds consisting of a multifunctional core group onto which further branched monomers are added in a regular way giving a tree-like structure, as described e.g. in M. Fischer and F. Vögtle, Angew. Chem., Int. Ed. 1999, 38, 885.

The term “conjugated polymer” means a polymer containing in its backbone (or main chain) mainly C atoms with sp²-hybridisation, or optionally sp-hybridisation, which may also be replaced by hetero atoms, enabling interaction of one n-orbital with another across an intervening σ-bond. In the simplest case this is for example a backbone with alternating carbon-carbon (or carbon-hetero atom) single and multiple (e.g. double or triple) bonds, but does also include polymers with units like 1,3-phenylene. “Mainly” means in this connection that a polymer with naturally (spontaneously) occurring defects, which may lead to interruption of the conjugation, is still regarded as a conjugated polymer. Also included in this meaning are polymers wherein the backbone comprises for example units like aryl amines, aryl phosphines and/or certain heterocycles (i.e. conjugation via N-, O-, P- or S-atoms) and/or metal organic complexes (i.e. conjugation via a metal atom). The term “conjugated linking group” means a group connecting two rings (usually aromatic rings) consisting of C atoms or hetero atoms with sp²-hybridisation or sp-hybridisation. See also “IUPAC Compendium of Chemical terminology, Electronic version”.

Unless stated otherwise, the molecular weight is given as the number average molecular weight Mₙ or as weight average molecular weight M_{w}, which unless stated otherwise are determined by gel permeation chromatography (GPC) against polystyrene standards.

The degree of polymerization (n) means the number average degree of polymerization, unless stated otherwise given as n=Mₙ/M_{U}, wherein M_{U} is the molecular weight of the single repeating unit.

The term “small molecule” means a monomeric, i.e. a non-polymeric compound.

Unless stated otherwise, percentages of solids are per cent by weight (“wt. %”), percentages or ratios of liquids (like e.g. in solvent mixtures) are per cent by volume (“vol. %”), and all temperatures are given in degrees Celsius (° C.).

Unless stated otherwise, concentrations or proportions of mixture components, like the conductive additives, given in percentages or ppm are related to the entire formulation including the solvents.

The invention will now be described in more detail by reference to the following examples, which are illustrative only and do not limit the scope of the present invention.

### WORKING EXAMPLES

The following materials were used in the working examples:

3,4-Dimethylanisole, tetraoctylammonium bromide and trifluoroacetic acid were purchased from Sigma-Aldrich.

Triethylamine was purchased from VWR.

Tributylammonium trifluoroacetate was obtained by adding a 1:1 molar ratio of tributylamine and trifluoroacetic acid to the solution. First tributylamine was added to the solution followed by trifluoroacetic acid.

Triethylammonium trifluoroacetate was obtained by adding a 1:1 molar ratio of triethylamine and trifluoroacetic acid using the method above.

Conductivity (C) was obtained from calculated resistivity p using the following equations:

$$C = \frac{1}{ρ} [ S \text{/} m ] , \\ where ρ = \frac{RA}{l} = R \times \frac{1}{k} = \frac{R}{k} [ Ω m ] ,$$

and the cell constant k=I/A was determined from the cell dimensions, where I was the distance between the electrodes and A was the area of electrodes and R=V/I [Ω].

Measurements were performed by placing each solution into a cylindrical measurement cell of known dimensions. The conductivity cell consisted of an inner cylindrical electrode contained within an outer cylindrical electrode. The electrodes were all separated with PTFE spacers.

A Novacontrol ALHPA A or Agilent 4155C analyzer was then used to record the current (I) passing as the voltage (V) was scanned from −0.5 V to 0.5 V and the linear region of the plot from −0.2 to 0.2 V was used to derive the conductivity using the equation above where the constant k=368 m⁻¹ was used.

### Example 1

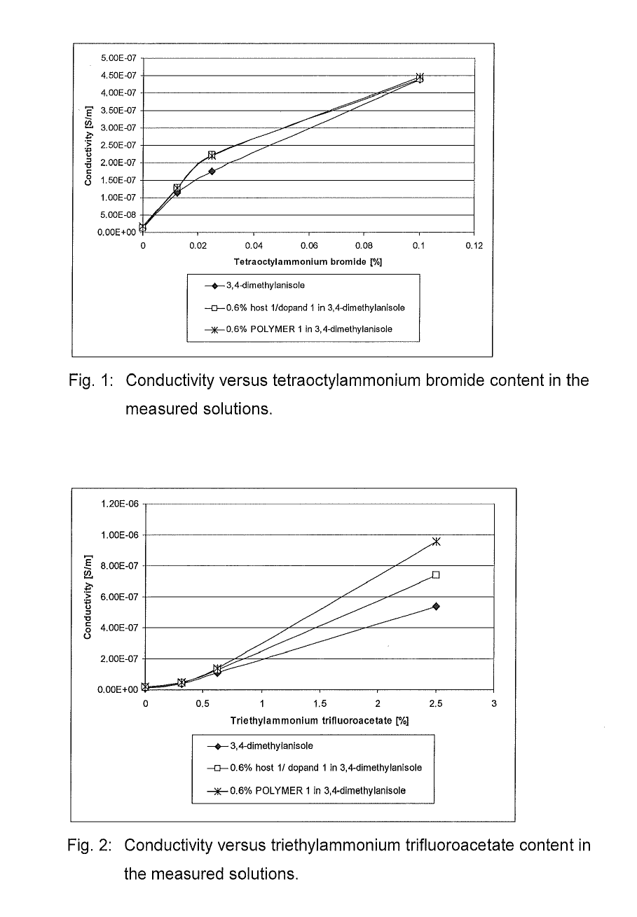

The resistance of o-xylene, tetraoctylammonium bromide in o-xylene, tributylammonium trifluoroacetate in o-xylene, 3,4-dimethylanisole, tetraoctylammonium bromide in 3,4-dimethylanisole and triethyl-ammonium trifluoroacetate in 3,4-dimethylanisole were measured and the conductivities were calculated. The results are presented in Table 1 and displayed as a function of the concentration in FIGS. 1 and 2.

TABLE 1

| | | Liquid |
|---|---|---|
| | Additive and its concentration | conductivity |
| Solvent | [wt. %] | [S/m] |
| air | 0 (control) | 1.19 × 10⁻¹² |
| o-xylene | 0 (control) | 1.55 × 10⁻⁹ |
| o-xylene | tetraoctylammonium bromide, | 2.70 × 10⁻⁸ |
| | 0.025 | |
| o-xylene | tributylammonium | 4.73 × 10⁻⁸ |
| | trifluoroacetate, 1.0 | |
| 3,4-dimethylanisole | 0 (control) | 1.14 × 10⁻⁸ |
| 3,4-dimethylanisole | tetraoctylammonium bromide, | 1.07 × 10⁻⁷ |
| | 0.0125 | |
| 3,4-dimethylanisole | tetraoctylammonium bromide, | 1.76 × 10⁻⁷ |
| | 0.025 | |
| 3,4-dimethylanisole | tetraoctylammonium bromide, | 4.38 × 10⁻⁷ |
| | 0.1 | |
| 3,4-dimethylanisole | triethylammonium | 4.00 × 10⁻⁸ |
| | trifluoroacetate, 0.3125 | |
| 3,4-dimethylanisole | triethylammonium | 1.10 × 10⁻⁷ |
| | trifluoroacetate, 0.625 | |
| 3,4-dimethylanisole | triethylammonium | 5.36 × 10⁻⁷ |
| | trifluoroacetate, 2.5 | |

The samples containing a conductive additive had a higher conductivity than the corresponding control sample without a conductive additive.

### Example 2

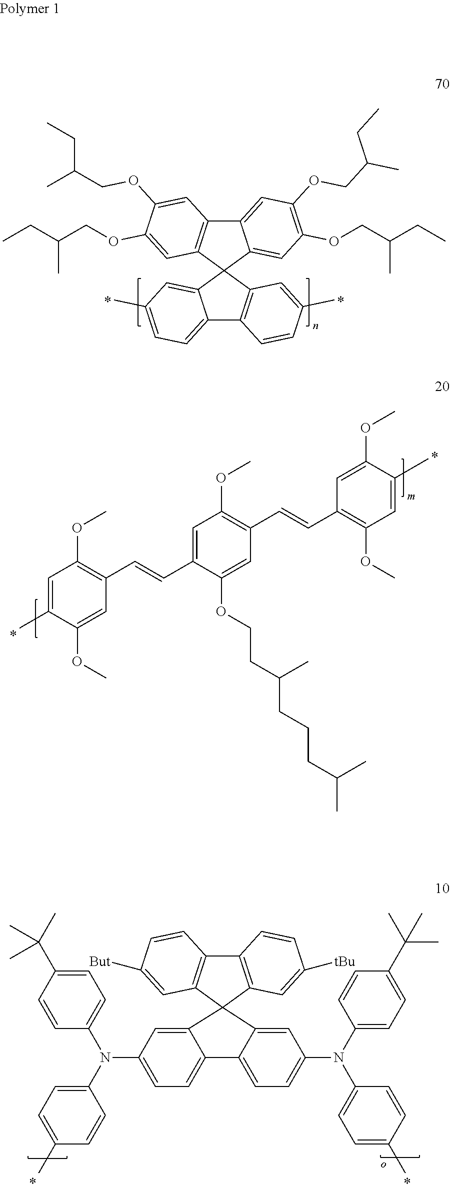

0.6 parts of Polymer 1 (c.f. Example 6 in EP 1741148) were dissolved in 99.4 parts of 3,4-dimethylanisole (0.6% of Polymer 1 in 3,4-dimethylanisole).

The resistance of Polymer 1 solution, tetraoctylammonium bromide in Polymer 1 solution and triethylammonium trifluoroacetate in Polymer 1 solution were measured and the conductivities were calculated as described in Example 1. The results are presented in Table 2 and displayed as a function of the concentration in FIGS. 1 and 2.

TABLE 2

| | | Liquid |
|---|---|---|
| | Additive and its concentration | conductivity |
| Solution | [wt. %] | [S/m] |
| 0.6% w/w POLYMER 1 | 0 (control) | 1.86 × 10⁻⁸ |
| in 3,4-dimethylanisole | | |
| 0.6% w/w POLYMER 1 | tetraoctylammonium bromide, | 1.29 × 10⁻⁷ |
| in 3,4-dimethylanisole | 0.0125 | |
| 0.6% w/w POLYMER 1 | tetraoctylammonium bromide, | 2.20 × 10⁻⁷ |
| in 3,4-dimethylanisole | 0.025 | |
| 0.6% w/w POLYMER 1 | tetraoctylammonium bromide, | 4.47 × 10⁻⁷ |
| in 3,4-dimethylanisole | 0.1 | |
| 0.6% w/w POLYMER 1 | triethylammonium | 4.85 × 10⁻⁸ |
| in 3,4-dimethylanisole | trifluoroacetate, 0.3125 | |
| 0.6% w/w POLYMER 1 | triethylammonium | 1.36 × 10⁻⁷ |
| in 3,4-dimethylanisole | trifluoroacetate, 0.625 | |
| 0.6% w/w POLYMER 1 | triethylammonium | 9.59 × 10⁻⁷ |
| in 3,4-dimethylanisole | trilfuoroacetate, 2.5 | |

The samples containing a conductive additive had a higher conductivity than the corresponding control sample without a conductive additive.

### Example 3

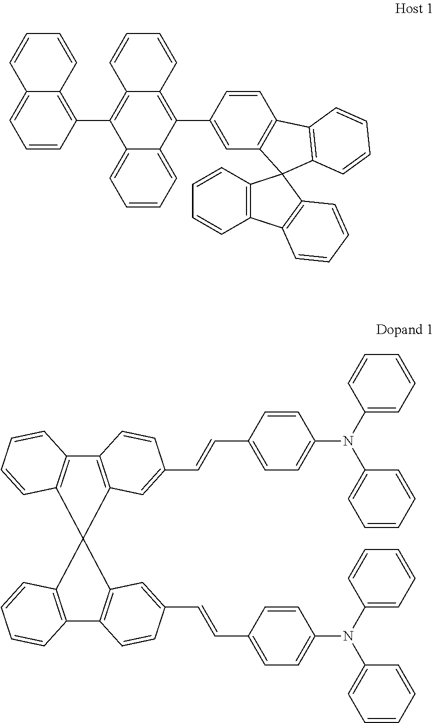

0.558 parts of Host 1 and 0.042 parts of Dopand 1 were dissolved in 99.4 parts of 3,4-dimethylanisole (0.6% Host 1/Dopand 1 in 3,4-dimethylanisole).

The resistance of Host 1/Dopand 1 solution, tetraoctylammonium bromide in Host 1/Dopand 1 solution and triethylammonium trifluoroacetate in Host 1/Dopand 1 solution were measured and the conductivities were calculated as described in Example 1. The results are presented in Table 3 and displayed as a function of the concentration in FIGS. 1 and 2.

TABLE 3

| | | Liquid |
|---|---|---|
| | Additive and its concentration | conductivity |
| Solution | [wt. %] | [S/m] |
| 0.6% host 1/dopand 1 | 0 (control) | 1.26 × 10⁻⁸ |
| in 3,4-dimethylanisole | | |
| 0.6% host 1/dopand 1 | tetraoctylammonium bromide, | 1.27 × 10⁻⁷ |
| in 3,4-dimethylanisole | 0.0125 | |
| 0.6% host 1/dopand 1 | tetraoctylammonium bromide, | 2.22 × 10⁻⁷ |
| in 3,4-dimethylanisole | 0.025 | |
| 0.6% host 1/dopand 1 | tetraoctylammonium bromide, | 4.41 × 10⁻⁷ |
| in 3,4-dimethylanisole | 0.1 | |
| 0.6% host 1/dopand 1 | triethylammonium | 4.10 × 10⁻⁸ |
| in 3,4-dimethylanisole | trifluoroacetate, 0.3125 | |
| 0.6% host 1/dopand 1 | triethylammonium | 1.30 × 10⁻⁷ |
| in 3,4-dimethylanisole | trifluoroacetate, 0.625 | |
| 0.6% host 1/dopand 1 | triethylammonium | 7.40 × 10⁻⁷ |
| in 3,4-dimethylanisole | trifluoroacetate, 2.5 | |

The samples containing a conductive additive had a higher conductivity than the corresponding control sample without a conductive additive.

1-16. (canceled)

17. A formulation comprising one or more organic light emitting materials and/or charge transporting materials, one or more organic solvents, and one or more additives that increase the conductivity of the formulation (conductive additives), wherein said conductive additives are volatile and/or are not capable of chemically reacting with the organic light emitting material and/or charge transporting material.

18. The formulation of claim 17, wherein the conductive additives are selected from the group consisting of non-oxidising organic salts, volatile organic salts, alcohols, volatile carboxylic acids and organic amines.

19. The formulation of claim 18, wherein the conductive additives are selected from the group consisting of quaternary ammonium salts, phosphonium salts, imidazolium salts and other heterocyclic salts, wherein the anion is selected from the group consisting of halides, sulfates, acetate, formate, tetrafluoroborate, hexafluorophosphate, methanesulfonate, triflate (trifluoromethanesulfonate), and bis(trifluoromethylsulfonyl)imide.

20. The formulation of claim 18, wherein the conductive additives are selected from the group consisting of isopropylalcohol, iso-butanol, hexanol, methanol, ethanol, formic acid, acetic acid, di- or trifluoroacetic acid, and primary or secondary alkyl amines.

21. The formulation of claim 17, wherein the conductive additive are present in a total concentration of less than 5% by weight.

22. The formulation of claim 17, wherein it has a conductivity from 10⁻⁵ to 10⁻⁹ S/m.

23. The formulation of claim 17, wherein the solvents are selected from the group consisting of aromatic hydrocarbons, anisole, alkylanisole, naphthalene derivatives, alkyl naphthalenes, dihydronaphthalene derivatives, tetrahydronaphthalene derivatives, aromatic esters, aromatic ketones, alkylketones, heteroaromatic solvents, halogenaryles, and aniline derivatives.

24. The formulation of claim 23, wherein the solvents are selected from the group consisting of toluene, o-, m- or p-xylene, trimethyl benzenes, tetralin, other mono-, di-, tri- and tetraalkyl-benzenes, anisole, alkyl anisoles, naphthalene derivatives, alkyl naphthalene derivatives, and di- and tetrahydronaphthalene derivatives.

25. The formulation of claim 17, wherein the organic light emitting materials and charge transporting materials are selected from the group consisting of (i) substituted poly-p-arylenevinylenes (PAVs), (ii) substituted polyfluorenes (PFs), (iii) substituted polyspirobifluorenes (PSFs), (iv) substituted poly-para-phenylenes (PPPs) or -biphenylenes, (v) substituted polydihydrophenanthrenes (PDHPs), (vi) substituted poly-trans-indenofluorenes and poly-cis-indenofluorenes (PIFs), (vii) substituted polyphenanthrenes, (viii) substituted polythiophenes (PTs), (ix) polypyridines (PPys), (x) polypyrroles, (xi) substituted, soluble copolymers having structural units from two or more of classes (i) to (x), (xii) conjugated polymers disclosed in Proc. of ICSM '98, Part I & II (in: Synth. Met 1999, 101/102) which are soluble in organic solvents, (xiii) substituted and unsubstituted polyvinylcarbazoles (PVKs), (xiv) substituted and unsubstituted triarylamine polymers, (xv) substituted and unsubstituted polysilylenes and polygermylenes, and (xvi) soluble polymers containing phosphorescent units.

26. The formulation of claim 17, wherein the organic light emitting materials are organic phosphoresecent compounds which emit light and in addition contain at least one atom having an atomic number greater than 38.

27. The formulation of claim 26, wherein the phosphorescent compounds are compounds of formulae (1) to (4): 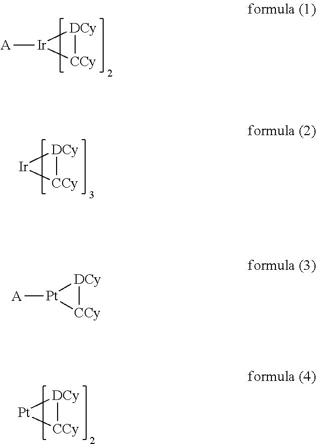
wherein
DCy is, identically or differently on each occurrence, a cyclic group which contains at least one donor atom via which the cyclic group is bonded to the metal, and which is optionally substituted with one or more substituents R¹; the groups DCy and CCy are connected to one another via a covalent bond
CCy is, identically or differently on each occurrence, a cyclic group which contains a carbon atom via which the cyclic group is bonded to the metal and which is optionally substituted with one or more substituents R¹;
A is, identically or differently on each occurrence, a monoanionic, bidentate chelating ligand;
R¹ is, identically or differently on each occurrence, F, Cl, Br, I, NO₂, CN, a straight-chain, branched or cyclic alkyl or alkoxy group having from 1 to 20 carbon atoms, in which one or more nonadjacent CH₂ groups is optionally replaced by —O—, —S—, —NR²—, —CONR²—, —CO—O—, —C═O—, —CH═CH—, or —C≡C—, and in which one or more hydrogen atoms is optionally replaced by F, or an aryl or heteroaryl group which has from 4 to 14 carbon atoms and is optionally substituted by one or more nonaromatic R¹ radicals, and a plurality of substituents R¹, either on the same ring or on the two different rings, together optionally define a mono- or polycyclic, aliphatic or aromatic ring system; and
R² is, identically or differently on each occurrence, a straight-chain, branched or cyclic alkyl or alkoxy group having from 1 to 20 carbon atoms, in which one or more nonadjacent CH₂ groups are optionally replaced by —O—, —S—, —CO—O—, —C═O—, —CH═CH—, or —C≡C—, and in which one or more hydrogen atoms are optionally replaced by F, or an aryl or heteroaryl group which has from 4 to 14 carbon atoms optionally substituted by one or more nonaromatic R¹ radicals.

28. The formulation of claim 17, wherein it comprises between 0.01 and 20% by weight of the organic light emitting materials and/or charge transporting materials based on 100% of the solvent or solvent mixture.

29. The formulation of claim 17, wherein it furthermore comprises dopants, host materials, hole-injection materials, hole-transport materials, electron-injection materials and/or electron-transport materials.

30. A coating or printing ink for the preparation of OLED devices comprising the formulation of claim 17.

31. A process for preparing an organic light emitting diode device, comprising the steps of
a) depositing the formulation of claim 17 onto a substrate to form a film or layer, and
b) removing the solvent(s) and any conductive additives that are volatile or capable of chemically reacting with the organic light emitting materials and/or charge transporting materials.

32. An OLED device prepared from the formulation of claim 17 or by the process of claim 31.
